(19) United States
(12) Patent Application Publication
(10) Pub. No.: US 2025/0046371 A1
(43) Pub. Date: Feb. 6, 2025

(54) IN-MEMORY COMPUTATION DEVICE WITH AT LEAST AN IMPROVED DIGITAL DETECTOR FOR A MORE ACCURATE CURRENT MEASUREMENT

(71) Applicant: STMicroelectronics International N.V., Geneva (CH)

(72) Inventors: Marco PASOTTI, Travaco' Siccomario (PV) (IT); Riccardo VIGNALI, Graffignana, LODI (IT); Alessandro CABRINI, San Genesio Ed Uniti, Pavia (IT); Riccardo ZURLA, Binasco, MI (IT)

(73) Assignee: STMicroelectronics International N.V., Geneva (CH)

(21) Appl. No.: 18/790,867

(22) Filed: Jul. 31, 2024

(30) Foreign Application Priority Data
Aug. 1, 2023 (IT) 102023000016299

(51) Int. Cl. G11C 13/00

(52) U.S. Cl. CPC G11C 13/0038; G11C 13/0004; G11C 13/0028

(57) ABSTRACT

An in-memory computation device receives an input signal and provides an output signal. The device includes a memory array with memory cells coupled to word lines that receive word line activation signals indicative of the input signal and coupled to bit lines that generate bit line currents; and a digital detector for sampling the bit line current and, in response, providing the output signal. A digital detector includes: a control stage that compares the bit line current with at least one reference current and generates corresponding control signals; a selection stage that generates a total selection current based on the first bit line current and on the control signals; an integration stage that samples the total selection current; and a charge counter stage that generates the output signal on the basis of a sampled first total selection current and the control signals.

### PRIORITY CLAIM

This application claims the priority benefit of Italian Application for Patent No. 102023000016299 filed on Aug. 1, 2023, the content of which is hereby incorporated by reference in its entirety to the maximum extent allowable by law.

### TECHNICAL FIELD

The present invention relates to an in-memory computation (IMC) device with at least an improved digital detector for a more accurate current measurement. The IMC device allows multiply and accumulate operations to be performed and the improved digital detector allows the currents generated by the IMC device to be sampled in a manner that is more homogeneous and less dependent on the values of the generated currents, so as to improve the measurement accuracy and therefore the calculation performances of the IMC device.

Furthermore, it relates to a control method of the IMC device.

### BACKGROUND

As is known, an in-memory computation device uses the specific arrangement of the memory cells of a memory array to perform analog data processing at cell level.

For example, in-memory computation devices are used to perform multiply and accumulate (MAC) operations, which are for example employed to implement machine learning algorithms, such as neural networks.

A multiply and accumulate operation provides an output vector y₁, . . . , y_{M} as the multiplication of an input vector x₁, . . . , x_{N} by a vector or matrix of computational weights gᵢⱼ, for example:

$$[ \begin{matrix}{y}_{1} \\ {y}_{2} \\ ⋮ \\ {y}_{m}\end{matrix} ] = [ \begin{matrix}{g}_{11} & {g}_{12} & … & {g}_{1 n} \\ {g}_{21} & {g}_{22} & … & {g}_{2 n} \\ ⋮ & ⋮ & ⋮ & ⋮ \\ {g}_{m 1} & {g}_{m 2} & … & {g}_{mn}\end{matrix} ] \times [ \begin{matrix}{x}_{1} \\ {x}_{2} \\ ⋮ \\ {x}_{n}\end{matrix} ] , i . e . :$$

$$\{ \begin{matrix}{y}_{1} = {g}_{11} \cdot {x}_{1} + {g}_{12} \cdot {x}_{2} + … + {g}_{1 N} \cdot {x}_{N} \\ {y}_{2} = {g}_{21} \cdot {x}_{1} + {g}_{22} \cdot {x}_{2} + … + {g}_{2 N} \cdot {x}_{N} \\ ⋮ \\ {y}_{M} = {g}_{M 1} \cdot {x}_{1} + {g}_{M 2} \cdot {x}_{2} + … + {g}_{MN} \cdot {x}_{N}\end{matrix} .$$

The in-memory computation device stores the computational weights gᵢⱼ in the memory cells and performs the multiplication and sum operations at cell level.

In detail, for each output vector yᵢ, known in-memory devices generate a current indicative of a respective MAC operation, i.e., Σᵢ₌₁^{i=M}gᵢⱼ·xⱼ, and comprise a reading circuit having a respective analog-to-digital converter (ADC) which discretizes said current.

In-memory computation devices allow the back and forth transfer of data between a memory and a processing circuit to be avoided. Consequently, the performance of an in-memory computation device is not limited by the data transfer bandwidth between memory and processing circuit and has low power consumption.

However, it is recognized that, in known in-memory computation devices, the measured current indicative of the MAC operation is subject to errors due to the operation of the ADC. Therefore, known in-memory computation devices have low computational accuracy.

In particular, the ADC has a non-linear behavior in response to the currents to be measured, especially in case of high currents.

In fact, ideally the charge packets measured by the ADC in response to the current at the input of the ADC should be independent of the current to be measured, thus ensuring an accurate measurement which does not depend on the value of the same current to be measured. In other words, in an ideal case each measured charge packet should have the same amount of charge.

Nevertheless, it has been verified that the amount of charge present in the measured charge packets in fact varies according to the current to be measured.

In fact, as shown in FIG. 1, during the measurement of each charge packet the ADC has a delay interval t_{d} between the moment in which the switching threshold voltage V_{th,sw} (indicative of the achievement of the predefined amount of charge which identifies the ideal charge packet and which should ideally cause the resulting switching of a feedback loop circuit of the ADC) is reached and the moment in which the feedback loop circuit of the ADC actually switches terminating the measurement of the charge packet considered. During this delay interval t_{d} the ADC continues to measure the current although the switching threshold voltage V_{th,sw} has already been reached. This causes each charge packet to have an additional and unwanted amount of charge, acquired during the delay interval t_{d} and also indicated hereinafter with the reference Q_{add}. This additional amount of charge Q_{add} depends on the delay interval t_{d} (which however is generally constant as it depends almost exclusively on the design of the ADC) and on the current measured at that moment by the ADC, and in particular it grows as the current grows. For example, FIG. 1 shows the differences present between the charge packets measured at different currents (in particular, at three different currents which correspond to the respective angles of the three voltage lines V shown in FIG. 1). Consequently, as the current to be measured varies, the additional amounts of charge vary and therefore the current is discretized into charge packets which are not uniform with each other.

As may be seen in FIG. 2, the trend of the additional amount of charge Q_{add} measured by the ADC is non-linear as the amount of charge Qᵣₑₐₗ actually received at input by the ADC varies and its offset with respect to the reference case in which the additional amount of charge Q_{add} is independent of the input current is minimum at low currents and increases as the current increases. Consequently, especially at high currents, the measurements carried out by known-type ADCs are not accurate and do not correspond to the real currents generated by the in-memory computation devices.

As evident, this reduces the measurement accuracy of the currents generated by the in-memory computation device and therefore worsens its computational performances.

A known solution to this issue is, for example, that of reducing the frequency of the charge counter of the ADC by increasing the size and storage capacity of the storage capacitors of the ADC, or that of decreasing the current at the input of the ADC. However, reducing the frequency of the charge counter causes either a reduction in the measurement resolution (because a lower number of bits is available) or an increase in the time required to perform the measurement.

Another known solution is to use a “feed forward” circuit in the ADC to dynamically update the switching threshold voltage V_{th,sw} as a function of the current at the input of the ADC. However, this requires a complicated and expensive calibration process.

Another known solution is to use post-processing methods to replace the actually measured current value with a real current value. This is done, for example, using a look-up table in which each actually measured current value (i.e., affected by the error due to the additional amount of charge Q_{add} in each measured charge packet) is associated with a respective current value actually generated by the in-memory computation device. However, this solution only works if the current to be measured remains constant during integration by the ADC.

In other words, none of the currently known solutions is capable of solving the previously listed issue in an optimal manner.

There is a need in the art is to overcome the foregoing drawbacks.

### SUMMARY

According to the present invention, an in-memory computation device and a control method thereof are provided.

In an embodiment, an in-memory computation (IMC) device is configured to receive an input signal indicative of a plurality of input values and to provide at least an output signal indicative of a plurality of output values. The IMC device comprises: a word line activation circuit configured to receive the input signal and to provide a plurality of word line activation signals, each being a function of a respective input value of the input values; a biasing circuit configured to provide a biasing voltage; a memory array comprising a plurality of first memory cells coupled to a first bit line and each coupled to a respective word line, the first bit line being configured to receive the biasing voltage, the first memory cells being configured to each store a respective computational weight and to each receive from the respective word line a respective word line activation signal of the plurality of word line activation signals, the first memory cells being configured to be each traversed by a respective cell current which is a function of the biasing voltage, of the respective word line activation signal and of the respective computational weight, the first bit line being configured to be traversed by a first bit line current which is a sum of the cell currents; and a first digital detector coupled to the first bit line and configured to sample the first bit line current and, in response to the first bit line current, provide the output signal.

The first digital detector comprises: a control stage electrically coupled to the first bit line and configured to receive the first bit line current, generate at least a first main control mirrored current in response to the first bit line current, compare the first main control mirrored current with at least a first reference current and generate one or more control signals indicative of said comparison; a selection stage electrically coupled to the control stage and the first bit line and configured to receive the first bit line current and the one or more control signals and generate a total selection current in response to the first bit line current and as a function of the one or more control signals; an integration stage electrically coupled to the selection stage and configured to receive and sample the total selection current; and a charge counter stage electrically coupled to the integration stage and to the control stage and configured to receive the total selection current sampled and the one or more control signals and generate, as a function of the one or more control signals, the output signal in response to the sampling of the first total selection current.

In an embodiment, a method for controlling an in-memory computation (IMC) device, such as the foregoing device, comprises: providing, by the word line activation circuit, the plurality of word line activation signals to the first memory cells; generating, by the biasing circuit, the biasing voltage and applying the biasing voltage to the first bit line; generating, by the control stage, the at least a first main control mirrored current in response to the first bit line current; comparing, by the control stage, the at least a first main control mirrored current with the at least a first reference current; generating, by the control stage, the one or more control signals indicative of said comparison; generating, by the selection stage, the total selection current in response to the first bit line current and as a function of the one or more control signals; sampling, by the integration stage, the total selection current; and generating, by the charge counter stage and as a function of the one or more control signals, the output signal in response to sampling the first total selection current.

### BRIEF DESCRIPTION OF THE DRAWINGS

For a better understanding of the present invention, a preferred embodiment is now described, purely by way of non-limiting example, with reference to the attached drawings, wherein: FIGS. 1 and 2 are plots of respective electrical quantities generated by known-type in-memory computation devices;

FIG. 3 shows a block diagram of an embodiment for an in-memory computation device;

FIG. 4 shows a circuit diagram of a line activation circuit of the in-memory computation device of FIG. 3;

FIG. 5 shows a circuit diagram of a timer of the line activation circuit of FIG. 4;

FIG. 6 shows a detailed circuit diagram of a portion of the timer of FIG. 5;

FIG. 7 shows a circuit diagram of an input-to-time converter of the line activation circuit of FIG. 4,

FIG. 8 shows an example of activation signals provided by the input-to-time converter of FIG. 7;

FIG. 9 shows a circuit diagram of a digital detector of the in-memory computation device of FIG. 3;

FIG. 10 shows a detailed circuit diagram of a portion of the digital detector of FIG. 9;

FIG. 11 shows exemplary waveforms generated by the digital detector of FIG. 9 in use; and

FIG. 12 shows a circuit diagram of a biasing circuit of the in-memory computation device of FIG. 3.

### DETAILED DESCRIPTION

In the following description, elements common to the different embodiments have been indicated with the same reference numerals.

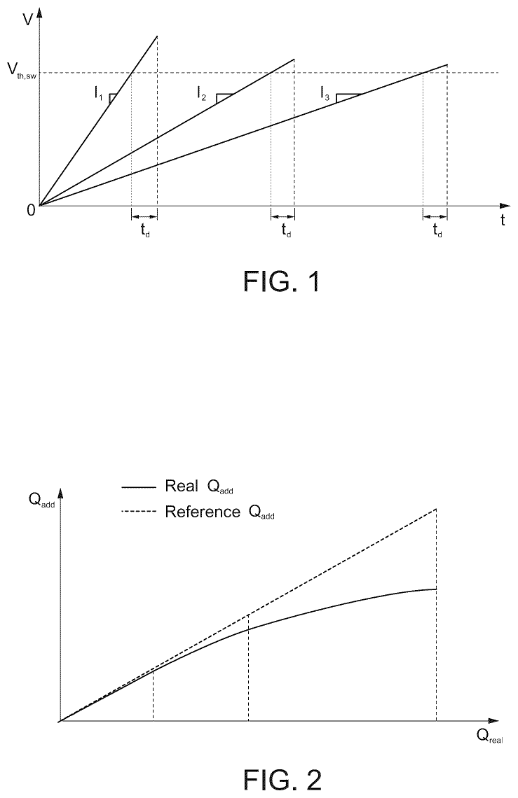

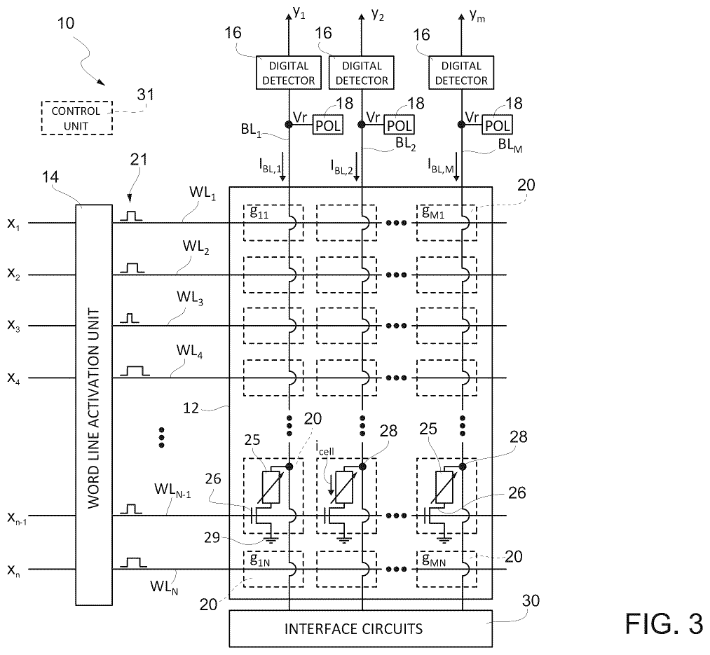

FIG. 3 shows an in-memory computation device 10, hereinafter also referred to as IMC device 10, comprising a computation memory array (or matrix) 12, hereinafter referred to as memory array 12, a word line activation circuit 14, a plurality of digital detectors 16 and a biasing circuit 18.

The memory array 12 is of non-volatile type and comprises a plurality of memory cells 20 organized according to a matrix arrangement having M columns and N rows.

The memory array 12 is configured to perform multiply and accumulate (MAC) operations in response to an input vector (or signal) X with input data x₁, . . . , xₙ (in general, with n≤N and, in the example of FIG. 3, in particular n=N), in order to generate an output vector (or signal) Y with output data y₁, . . . , yₘ (in general, with m≤M and, in the example of FIG. 3, in particular m=M).

The memory cells 20 arranged in the same column are mutually connected through a respective bit line BLᵢ, wherein i=1, . . . , M. The memory cells 20 arranged in the same row are mutually connected through a respective word line WLⱼ, wherein j=1, . . . , N.

In practice, a respective word line WLⱼ and a respective bit line BLᵢ are associated with each memory cell 20.

The memory cells 20 are programmed to each store a respective computational weight gᵢⱼ which may be used as a weight to perform an in-memory calculation such as a multiply and accumulate operation.

The word line activation circuit 14 provides a plurality of word line activation signals 21, one for each word line WLⱼ, which are configured to activate each the memory cells 20 of a respective word line WLⱼ, as discussed in detail hereinafter.

The word line activation circuit 14 receives the input vector X including the plurality of input values x₁, . . . , xₙ, for example one for each word line WLⱼ as exemplarily shown in FIG. 3.

The word line activation signals 21 are pulses, in particular here rectangular pulses, each having a time duration (i.e., pulse width) which is a function of the respective input value xⱼ.

The biasing circuit 18 generates a biasing voltage Vr in a per se known manner and provides the biasing voltage Vr to the bit lines BL₁, . . . , BL_{M}, as discussed in detail hereinafter. In particular and as shown in FIG. 3, the biasing circuit 18 is electrically coupled to the bit lines BL₁, . . . , BL_{M}, for example between the memory cells 20 and the digital detectors 16.

In this embodiment, the biasing circuit 18 provides the same voltage Vr to all the bit lines BL₁, . . . , BL_{M}. However, the biasing circuit 18 may provide the bit lines BL₁, . . . , BL_{M}, in response to the biasing voltage Vr, with biasing voltages different from each other, according to the specific application.

The digital detectors 16 are analog-to-digital converters (ADC) which are each coupled to a respective bit line BLᵢ and each provide a respective output datum yᵢ by sampling a current IB_{L,i} flowing through the respective bit line BLᵢ.

The memory cells 20 each comprise a storage element 25 and a selection element 26.

The storage element 25 of each memory cell 20 is a variable resistive element, in particular here based on a Phase Change Material (PCM), such as for example a chalcogenide.

In detail, the computational weight gᵢⱼ indicates the transconductance value of the storage element 25 of the respective memory cell 20, i.e., it is indicative of the programmed resistance of the storage element 25.

A phase change material has at least two phase states, for example an amorphous phase and a crystalline phase, each having a respective resistivity.

A phase change material may be transformed from one phase state to another by means of heat transfer, for example using current pulses.

The resistance of each storage element 25 associated with the respective phase state is used to distinguish two or more logic states of the corresponding memory cell 20.

For example, the amorphous phase may have higher resistance than the crystalline phase. A logic state ‘0’, or reset state, may be associated with the amorphous phase of the storage element 25. A logic state ‘1’, or set state, may be associated with the crystalline phase of the storage element 25.

The storage element 25 has a first terminal coupled to a node 28 of the respective bit line BLᵢ and a second terminal coupled to a reference potential node, here to ground 29, through the selection element 26.

The selection element 26 is a switch, for example a BJT transistor, a diode or a MOS transistor, here an NMOS transistor, which is arranged in series with the respective storage element 25 and whose switching is controlled by the word line activation signal 21 of the respective word line WLⱼ.

In this embodiment, the NMOS transistor forming the selection element 26 has a source coupled, here directly connected, to the ground 29; a drain coupled, here directly connected, to the second terminal of the storage element 25; and a gate coupled, here directly connected, to the respective word line WLⱼ.

In practice, the storage element 25 and the selection element 26 form a current path of the respective memory cell 20; the selection element 26, in response to receiving the respective activation signal 21, closes the respective current path, thereby allowing the flow of a cell current i_{cell} from the common node 28 to the ground 29.

The IMC device 10 may further comprise interface circuits 30 coupled to the bit lines BL₁, . . . , BL_{M} which may be used, for example, to program the transconductance values gᵢⱼ stored in the storage elements 25, in a per se known manner.

Furthermore, the IMC device 10 may also comprise a control circuit 31 operatively coupled to the word line activation circuit 14, the digital detectors 16 and the interface circuits 30, to control these components of the IMC device 10. Alternatively, the control circuit 31 may be external to the IMC device 10 and operatively coupled to the latter to operate in a similar manner to what has been previously described. In this case, the IMC device 10 and the control circuit 31 are, for example, comprised in an in-memory computation apparatus (not shown).

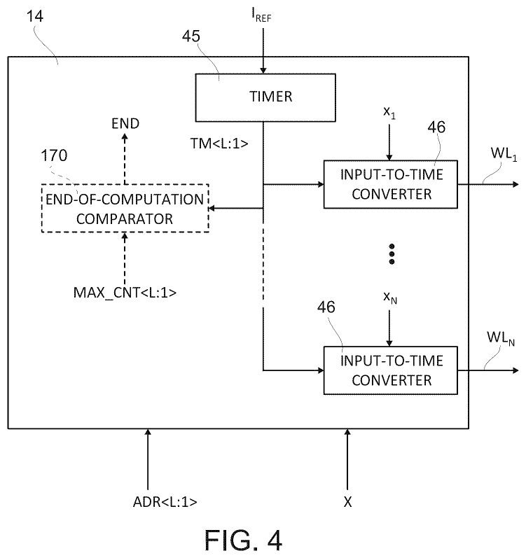

FIG. 4 shows a detailed and exemplary embodiment of the word line activation circuit 14.

The word line activation circuit 14 comprises a timer (or main counter) 45 providing a timer signal TM, and a plurality of input-to-time converters 46, one for each word line WL₁, . . . , WL_{N}.

The plurality of input-to-time converters 46 each receive the timer signal TM and the respective input value xⱼ and, in response, provide a respective word line activation signals 21.

The word line activation circuit 14 also receives an address signal ADR indicating which word lines WLⱼ to activate to perform an in-memory calculation. For example, the address signal ADR may be generated by the control circuit 31 and may be used to cause the activation, in use, of only some of the word lines WLⱼ, for example if the input vector X has a number nₘₐₓ of input data xⱼ lower than the number N of word lines WLⱼ of the memory array 12.

For example, the address signal ADR may be an N-bit digital signal ADRⱼ, with j=1, N (i.e., one for each word line WLⱼ). Each bit ADRⱼ of the address signal ADR corresponds to a respective word line WLⱼ and may for example be equal to logic 1 in case the word line WLⱼ is to be enabled or it may be equal to logic 0 in case the word line WLⱼ is to be disabled. For example, ADR=‘111 . . . 1000’ implies that the last three word lines WLⱼ are not used while the remaining are used.

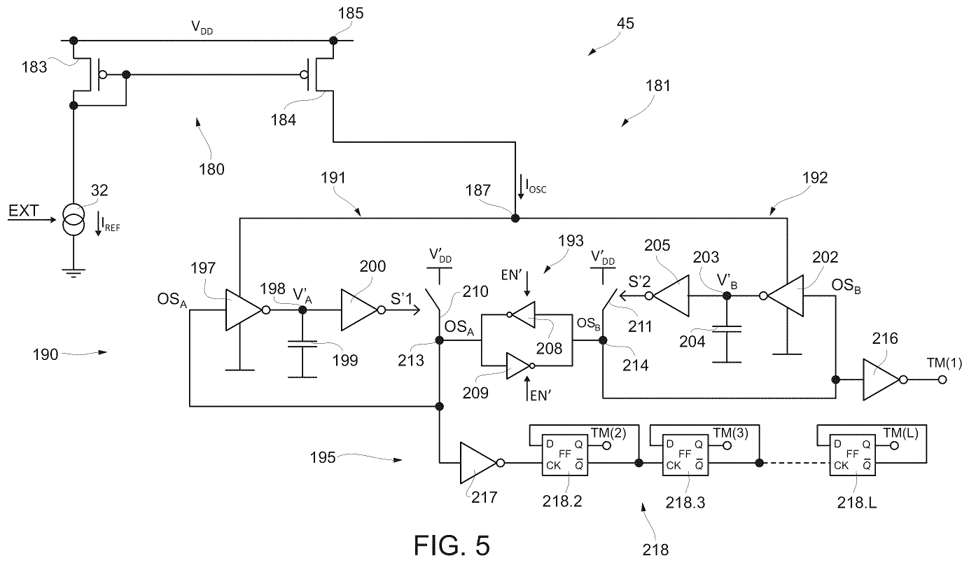

According to one embodiment, the timer 45 provides the timer signal TM in response to a supply current, hereinafter referred to as reference current I_{REF}. For example, the reference current I_{REF} is generated by a current source (of known type and indicated in FIG. 5 with the reference 32), in a per se known manner.

The timer signal TM is an L-bit digital signal, indicated hereinafter and in the Figures also as timer signal TM<L:1>, which increases over time at an update frequency fᵤ function of the supply current.

In practice, the timer signal TM is a counter signal.

The timer 45 may reset the timer signal TM to a start value, for example to zero, at the beginning of a new computation that is to be performed by the IMC device 10, for example in response to receiving a start signal from a user of the IMC device 10.

According to an embodiment, again with reference to FIG. 4, the word line activation circuit 14 may further comprise an end-of-computation comparator 170.

The end-of-computation comparator 170 receives the timer signal TM<L:1> and a maximum count signal MAX_COUNT<L:1> and provides, in response, an end-of-count signal END.

The maximum count signal MAX_COUNT<L:1> may be configured by a user of the IMC device 10 and indicates the maximum duration of a calculation performed by the IMC device 10. For example, the maximum count signal MAX_COUNT<L:1> may indicate a maximum duration equal to or greater than the time that any output data yᵢ would take to reach the respective maximum value, for example with all the bits equal to 1, when all the memory cells 20 associated with the respective bit line BLᵢ are activated. However, the maximum count signal MAX_COUNT<L:1> may indicate a lower maximum duration, for example if it is desired to obtain a shorter computation time by the IMC device 10.

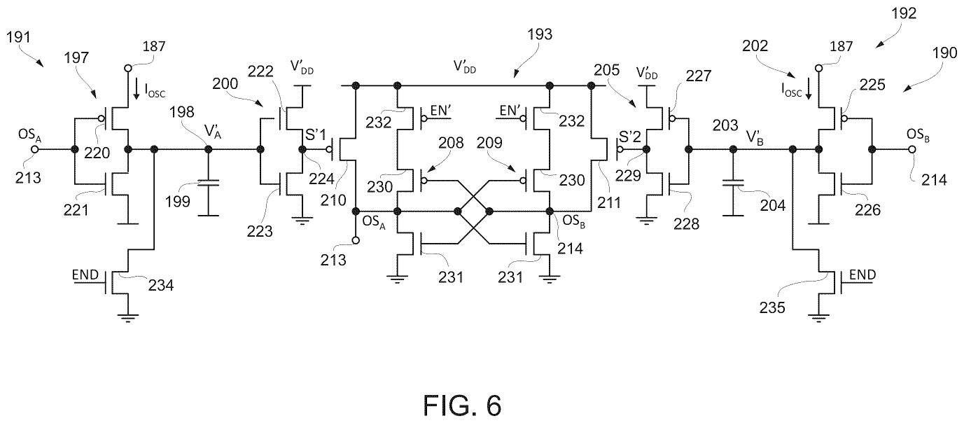

An exemplary and non-limiting embodiment of the timer 45 is described in detail with reference to FIGS. 5 and 6.

In FIG. 5, the timer 45 comprises a current mirror 180 which generates an oscillator current I_{OSC} in response to the reference current I_{REF}, and a count portion 181 which provides the timer signal TM from the oscillator current I_{OSC}.

The current mirror 180 has a mirroring ratio 1:p, so that the oscillator current I_{OSC} is p·I_{REF}.

In detail, the current mirror 180 has a first branch, here formed by a respective PMOS transistor 183, coupled to the current source 32, and a second branch, here formed by a respective PMOS transistor 184, coupled to the count portion 181.

The sources of the PMOS transistors 183, 184 are coupled to a supply node 185, here at a supply voltage V_{DD}, the gates of the PMOS transistors 183, 184 are mutually coupled to each other and to the drain of the PMOS transistor 183. The drain of the PMOS transistor 184 is coupled, in particular here is directly connected, to an input node 187 of the count portion 181.

The count portion 181 of the timer 45 comprises an integration stage 190, here formed by a first integration circuit 191, a second integration circuit 192 and a switching circuit 193 coupled between the first and the second integration circuits 191, 192, and a counter stage 195 which is coupled to the integration stage 190 and provides the timer signal TM.

The first and the second integration circuits 191, 192 are coupled to the input node 187 so as to receive the oscillator current I_{OSC}.

The first integration circuit 191 comprises a first inverter 197 having an output 198, a capacitor 199 of capacitance C′_{A} coupled to the output 198 of the first inverter 197, and a second inverter 200 whose input is coupled to the output 198 of the first inverter 197.

The first inverter 197 has a supply node coupled to the input node 187 of the count portion 181 (FIG. 6) and receives at input a first oscillator control signal OS_{A}.

In practice, the first inverter 197 is biased by the oscillator current I_{OSC}.

The capacitor 199 has a first terminal coupled to the output node 198 of the first inverter 197 and a second terminal coupled to a reference potential node, here to ground.

The output node 198 of the first inverter 197 is at a first oscillator integration voltage V′_{A} which drops across the capacitor 199.

The second inverter 200 has a first oscillator threshold V′ₜₕ₁, hereinafter simply referred to as first threshold V′ₜₕ₁, receives at input the first oscillator integration voltage V′_{A} and provides at output a first oscillator switch signal S′1 as a function of the first threshold V′ₜₕ₁ and of the first oscillator integration voltage V′_{A}.

In detail, when the first oscillator integration voltage V′_{A} is lower than the first threshold V′ₜₕ₁, the first oscillator switch signal S′1 has a high logic value. When the first oscillator integration voltage V′_{A} is higher than the first threshold V′ₜₕ₁, the first oscillator switch signal S′l has a low logic value.

The second integration circuit 192 comprises a first inverter 202 having an output 203, a capacitor 204 of capacitance C's coupled to the output 203 of the first inverter 202, and a second inverter 205 whose input is coupled to the output 203 of the first inverter 202.

The first inverter 202 has a supply node coupled to the input node 187 of the count portion 181 (FIG. 6) and receives at input a second oscillator control signal OS_{B}.

In practice, the first inverter 202 is biased by the oscillator current I_{OSC}.

The capacitor 204 has a first terminal coupled to the output node 203 of the first inverter 202 and a second terminal coupled to a reference potential node, here to ground.

The output node 203 of the first inverter 202 is at a second oscillator integration voltage V′_{B} which drops across the capacitor 204.

The second inverter 205 has a second oscillator threshold V′ₜₕ₂, hereinafter simply referred to as second threshold V′ₜₕ₂, receives at input the second oscillator integration voltage V′_{B} and provides at output a second oscillator switch signal S′₂ as a function of the second threshold V′ₜₕ₂ and of the second oscillator integration voltage V_{B}.

In detail, when the second oscillator integration voltage V_{B} is lower than the second threshold V′ₜₕ₂, the second oscillator switch signal S′₂ has a high logic value. When the second oscillator integration voltage V′_{B} is higher than the second threshold V′ₜₕ₂, the second oscillator switch signal S′₂ has a low logic value.

Again, with reference to FIG. 5, the switching circuit 193 is a latch formed by two inverters 208, 209 arranged in a ring configuration, a first switch 210 controlled by the first oscillator switch signal S′1 and a second switch 211 controlled by the second oscillator switch signal S′2.

The switching circuit 193 has a first node 213 coupled to the input of the inverter 209 and to the output of the inverter 208, and a second node 214 coupled to the output of the inverter 209 and to the input of the inverter 208.

The first node 213 provides the first oscillator control signal OS_{A}. The second node 214 provides the second oscillator control signal OS_{B}.

The first switch 210 is coupled between the first node 213 and a node at voltage V′_{DD}, the second switch 211 is coupled between the second node 214 and the node at voltage V′_{DD}.

In the embodiment of FIG. 5, the switching circuit 193 also receives an oscillator enable signal EN′, which controls the activation of the switching circuit 193. For example, the oscillator enable signal EN′ may be used to maintain the switching circuit 193 off when not in use, thereby allowing power consumption to be optimized. Furthermore, the enable signal EN′ may be used to set the switching circuit 193 to a defined state, for example when the IMC device 10 is switched on.

The counter stage 195 is coupled to the first and the second nodes 213, 214 of the switching circuit 193.

In detail, the charge counter stage 195 comprises an inverter 216, whose input is coupled to the second node 214, and a counter comprising an inverter 217 whose input is coupled to the first node 213 and a plurality of D-type flip-flops 218 including a first flip-flop 218.2, a second flip-flop 218.3 and a last flip-flop 218.L, wherein L is the number of bits of the timer signal TM<L:1>.

In practice, the counter of the charge counter stage 195 has L-1 flip-flops 218.

The output of the inverter 216 provides the first bit TM(1), i.e., the least significant bit, of the timer signal TM.

The flip-flops 218 are cascaded with each other, sequentially from the first flip-flop 218.2 to the last flip-flop 218.L.

The flip-flops 218 each have a clock input (CK-input), a data input (D-input), a Q-output and a Q̅-output.

The CK-input of the first flip-flop 218.2 is coupled to the output of the inverter 217. The Q̅-output of the first flip-flop 218.2 is fed back to the D-input of the first flip-flop 218.2. The Q-output of the first flip-flop 218.2 is the second bit TM(2) of the timer signal TM<L:1>.

The CK-input of the second flip-flop 218.3 is coupled to the Q̅-output of the first flip-flop 218.2. The Q̅-output of the second flip-flop 218.3 is fed back to the D-input of the second flip-flop 218.3. The Q-output of the second flip-flop 218.3 is the third bit TM(3) of the timer signal TM<L:1>.

What has been described for the second flip-flop 218.3 applies, mutatis mutandis, for all the successive flip-flops, here not shown, up to the L-1-th flip-flop, also not shown.

Finally, the CK-input of the last flip-flop 218.L is coupled to the Q̅-output of the L-1-th flip-flop. The Q̅-output of the last flip-flop 218.L is fed back to the D-input of the last flip-flop 218.L. The Q-output of the last flip-flop 218.L is the most significant bit TM(L) of the timer signal TM<L:1>.

With reference to the detailed implementation of the integration stage 190 shown in FIG. 6, the first inverter 197 of the first integration circuit 191 is a CMOS inverter formed by the series circuit of a PMOS transistor 220 and an NMOS transistor 221, mutually coupled to the output node 198. The PMOS and NMOS transistors 220, 221 receive the first oscillator control signal OS_{A} at the respective gate terminals.

The source of the PMOS transistor 220 is coupled to the input node 187 of the integration stage 190 of the timer 45.

The second inverter 200 of the first integration circuit 191 is a CMOS inverter formed by the series circuit of a PMOS transistor 222 and an NMOS transistor 223, mutually coupled to a node 224 providing the first oscillator switch signal S′1.

The first threshold V′ₜₕ₁ of the second inverter 200 is the switching threshold of the second inverter 200, and therefore depends on the properties, for example on the threshold or on-state resistance, of the PMOS and NMOS transistors 222, 223. In practice, the switching threshold may be the input voltage for which the output of the inverter has a high logic value or the input voltage for which the output of the inverter has a low logic value. For example, the switching threshold of the second inverter 200 may be defined as the operating point at which the respective input voltage, i.e., the first oscillator integration voltage V′_{A}, is equal to the respective output voltage, i.e., the first oscillator switch signal S′1.

The first inverter 202 of the second integration circuit 192 is a CMOS inverter formed by the series circuit of a PMOS transistor 225 and an NMOS transistor 226, mutually coupled to the output node 203. The PMOS and NMOS transistors 225, 226 receive the second oscillator control signal OS_{B} at the respective gate terminals.

The source of the PMOS transistor 225 is coupled to the input node 187 of the count portion 190 of the timer 45.

The second inverter 205 of the second integration circuit 192 is a CMOS inverter formed by the series circuit of a PMOS transistor 227 and an NMOS transistor 228, mutually coupled to a node 229 providing the second oscillator switch signal S′₂.

The second threshold V′ₜₕ₂ of the second inverter 205 is the switching threshold of the second inverter 205, and therefore depends on the properties, for example on the threshold or on-state resistance, of the PMOS and NMOS transistors 227, 228. In practice, the switching threshold may be the input voltage for which the output of the inverter has a high logic value or the input voltage for which the output of the inverter has a low logic value.

For example, the switching threshold of the second inverter 205 may be defined as the operating point at which the respective input voltage, i.e., the second oscillator integration voltage V′_{B}, is equal to the respective output voltage, i.e., the second oscillator switch signal S′2.

As shown in the detailed implementation of FIG. 6, the first and the second inverters 208, 209 of the switching circuit 193 are cross-coupled CMOS inverters each comprising a respective PMOS transistor 230 and a respective NMOS transistor 231 mutually coupled in series between a supply node, here at voltage V′_{DD}, and ground.

Furthermore, the first and the second inverters 208, 209 of the switching circuit 193 each also comprise a respective enable switch, here a PMOS transistor 232, which is coupled between the supply node at voltage V′_{DD} and the PMOS transistor 230 of the respective inverter.

The PMOS transistors 232 are controlled by the oscillator enable signal EN′.

In this embodiment, the timer 45 comprises, with reference to FIG. 6, a first and a second stopping switch, here a first and a second NMOS transistor 234, 235, which are configured to stop updating the timer signal TM by the timer 45.

In detail, the first and the second NMOS transistors 234, 235 have a drain terminal coupled to the output nodes 198, 203 of the first and, respectively, the second integration circuits 191, 192; and a source terminal coupled to a reference, here ground. The first and the second NMOS transistors 234, 235 receive, at the respective gate terminals, the end-of-count signal END.

When the end-of-computation comparator 170 (FIG. 4) switches the end signal END to the high logic value, the first and the second NMOS transistors 234, 235 are switched on, thereby short-circuiting to ground the output nodes 198, 203 of the first and the second integration circuits 191, 192.

Consequently, the timer 45 stops updating the timer signal TM.

Therefore, the timer 45 generates the timer signal TM<L:1> by performing a number of successive timing iterations. In each timing iteration, for example with reference to a timing iteration wherein the oscillator current I_{OSC} flows through the first integration circuit 191, the integration stage 190 generates the first oscillator integration voltage V′_{A} as time integral of the oscillator current I_{OSC}, compares the first oscillator integration voltage V′_{A} with the first threshold V′_{th,1} and, in response to the first oscillator integration voltage V′_{A} reaching the first threshold V′_{th,1}, resets the first oscillator integration voltage V′_{A}, in particular here by switching the first oscillator control signal OS_{A}. The counter stage 195 updates the timer signal TM<L:1> in response to the first oscillator integration voltage V′_{A} reaching the first threshold V′_{th,1}.

In this embodiment, the least significant bit of the timer signal TM is the value of the second oscillator control signal OS_{B}.

In other words, the timer 45 samples the oscillator current I_{OSC} by converting the oscillator current I_{OSC} into a number of charge packets and counting said charge packets, wherein each charge packet corresponds to the charge accumulated on the capacitors 199, 204 which causes a switching of the second inverters 200, 205.

As a result, the update frequency fᵤ of the timer signal TM<L:1> is given by the frequency of the switching events of the first oscillator control signal OS_{A}. The update frequency fᵤ therefore depends on the value of the oscillator current I_{OSC}, i.e., the reference current I_{REF} and on the mirror factor p of the current mirror 180, the capacitances C′_{A}, C′_{B}, and the first and the second thresholds V′_{th,1}, V′_{th,2} of the second inverters 200, 205.

In practice, the integration stage 110 of the timer 45 behaves as a current-controlled oscillator.

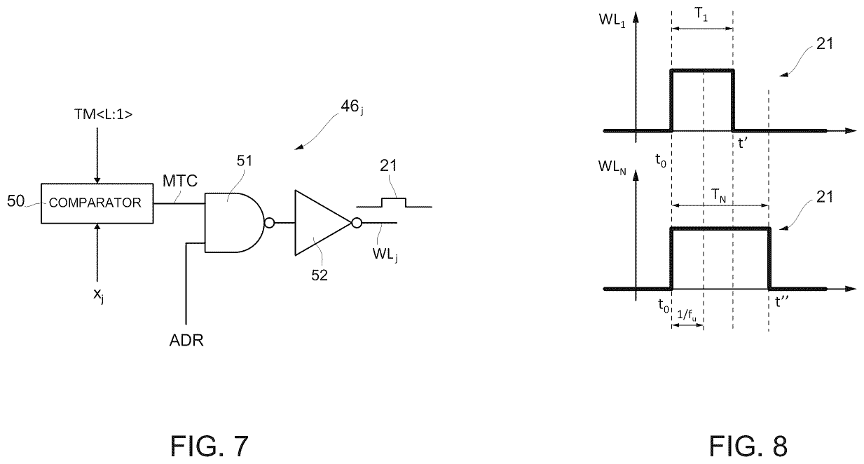

With reference to FIG. 7, an embodiment of the input-to-time converters 46 is now described. In particular and purely by way of example, FIG. 7 shows the input-to-time converter 46j of the word line WLⱼ of the plurality of word lines WL₁, . . . , WL_{N}.

The input-to-time converter 46j comprises a comparator 50 receiving the timer signal TM<L:1> and the respective input value xⱼ and providing, in response to these inputs, a corresponding match signal MTC.

In this embodiment, the input datum xⱼ is also a digital signal. The comparator 50, for example a bit verification circuit based on an XOR logic gate, compares the input datum xⱼ and the timer signal TM<L:1> and asserts the match signal MTC at the high logic value when the timer signal TM<L:1> becomes equal to the input datum xⱼ.

The input-to-time converter 46j further comprises a pulse generation circuit, here formed by a NAND logic gate 51 and an inverter 52, providing the respective word line activation signal 21 to the word line WLⱼ.

The NAND logic gate 51 receives the match signal MTC and the address signal ADR (in particular, its bit ADRⱼ) indicating whether the word line WLⱼ should be activated during the execution of an in-memory calculation. The address signal ADR may have a high logic value if the word line WLⱼ is to be activated during in-memory computation.

The inverter 52 is coupled at the input of the output of the NAND logic gate 51 and provides at output the word line activation signal 21. In practice, the inverter 52 operates as a drive circuit for the respective word line WLⱼ.

With reference to the word line WLⱼ, the input-to-time converter 46 maintains the respective word line activation signal 21 at the high logic value (i.e., thus activating, here, the selection elements 26 of the memory cells 20 coupled to the word line WLⱼ) as long as the timer signal TM<L:1> is different from the input datum xⱼ.

Therefore, the word line activation signals 21 each have a respective activation length Tⱼ which is proportional to the update frequency fᵤ of the timer signal TM<L:1> and to the respective input datum xⱼ.

FIG. 8 shows, by way of example, the word line activation signals 21 of the first word line WL₁ and of the last word line WL_{N}.

At the beginning of a computation by the IMC device 10 (time to) the timer signal TM is reset to the start value and the input-to-time converters 46 each switch the respective word line activation signal 21 to the high value.

In the example of FIG. 8, the input datum x₁ associated with the first word line WL₁ is lower than the input datum x_{N} associated with the last positive word line WL_{N}; therefore, the input-to-time converter 46 associated with the first word line WL₁ maintains the respective word line activation signal 21 at the high value for a shorter time with respect to the input-to-time converter 46 associated with the last word line WL_{N}. This entails that the word line activation signal 21 of the first positive word line WL₁ has an activation length Ti which is lower than the activation length T_{N} of the word line activation signal 21 of the last word line WL_{N}.

In use, the IMC device 10 may be used to perform a multiply and accumulate (MAC) operation between the input vector X=x₁, . . . , x_{N} and the matrix formed by the computational weights gᵢⱼ.

In fact, the cell current i_{cell} that each memory cell 20 absorbs, here from the respective node 28 to ground 29, depends on the transconductance gᵢⱼ of the respective storage element 25 and on the activation time Tⱼ of the respective selection element 26, i.e., on the length of the pulse of the respective word line activation signal 21.

In detail, the absolute value of each cell current i_{cell} depends on the respective transconductance value gᵢⱼ. The time duration of each cell current i_{cell} depends on the respective activation time Tⱼ.

Consequently, an electric charge may be associated with each cell current i_{cell}; said electric charge is a function of the respective transconductance value gᵢⱼ and the respective activation time Tⱼ.

Since the length of the pulse of the word line activation signals 21 is a function of the respective input value xⱼ, the electric charge associated with each cell current i_{cell} is a function of the product gᵢⱼ·xⱼ.

For each bit line BLᵢ, the respective bit line current I_{BL,i} is a sum of the cell currents i_{cell}. Therefore, the total electric charge associated with each bit line current I_{BL,i} is a function of the multiply and accumulate operation gᵢ₁·x₁+gᵢ₂·x₂+ . . . +g_{iN}·x_{N}.

Consequently, each output datum yᵢ, obtained by measuring the respective bit line current I_{BL,i}, in particular by integrating the respective bit line current I_{BL,i}, is indicative of the MAC operation gᵢ₁·x₁+gᵢ₂·x₂+ . . . +g_{iN}·x_{N}.

In the embodiment exemplarily shown in FIG. 3 and considered here, each bit line I_{BL,i} is electrically connected to a respective digital detector 16 of the digital detectors 16. Each digital detector 16 is configured to measure the bit line current I_{BL,i} that flows into the respective bit line I_{BL,i} and to generate the corresponding output datum yᵢ.

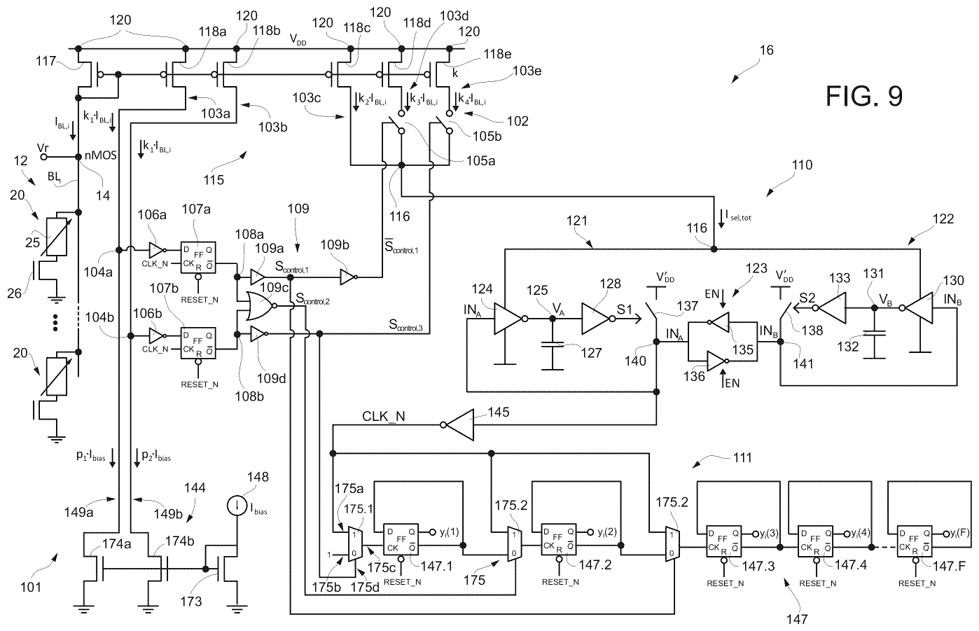

FIG. 9 shows an embodiment of the digital detectors 16. In detail, the digital detectors 16 are described below with reference to the digital detector 16 coupled to any bit line BLᵢ of the plurality of bit lines BLᵢ, . . . , BL_{M}.

The digital detector 16 comprises a control stage 101, a selection stage 102, an integration stage 110 and a charge counter stage 111.

The control stage 101 and the selection stage 102 are electrically connected to the bit line BLᵢ and in particular comprise and share a main current mirror 115 which mirrors the bit line current I_{BL,i} of the bit line BLᵢ (input branch of the main current mirror 115) in a plurality of control input branches 103a, 103b of the control stage 101 and of selection input branches 103c, 103d and 103e of the selection stage 102 (output branches of the main current mirror 115).

The main current mirror 115 has a respective mirror ratio for each of the input branches 103a, 103b, 103c, 103d and 103e considered.

In particular, the main current mirror 115 has a main control mirror ratio 1:k₁ for both the first control input branch 103a and the second control input branch 103b of the control stage 101 (generally k₁≤1 and in detail, in the embodiment considered here, the main control mirror ratio 1:k₁ is exemplarily unitary, i.e., k₁=1), has a first selection mirror ratio 1:k₂ (in the example considered here, k₂=1/4) for the first selection input branch 103c of the selection stage 102, has a second selection mirror ratio 1:k₃ (in the embodiment considered here equal to the first selection mirror ratio 1:k₂ and, in the example considered here, k₂=k₃=1/4) for the second selection input branch 103d of the selection stage 102 and has a third selection mirror ratio 1:k₄ (with mirroring coefficient equal to double the mirroring coefficient of the first selection mirror ratio 1:k₂ and, in the example considered here, k₄=1/2) for the third selection input branch 103e of the selection stage 102. In this manner, a main control mirrored current k₁·I_{BL,i} (here equal to the bit line current I_{BL,i} since k₁=1) flows through both the first control input branch 103a and the second control input branch 103b, a first selection mirrored current k₂·I_{BL,i} flows through the first selection input branch 103c, a second selection mirrored current k₃I_{BL,i} flows through the second selection input branch 103d and a third selection mirrored current k₄·I_{BL,i} flows through the third selection input branch 103e.

In detail, the main current mirror 115 has a first branch, here formed by a respective input PMOS transistor 117, coupled to the bit line BLᵢ, and a plurality of second branches in parallel with each other, i.e., the input branches 103a, 103b, 103c, 103d and 103e of the control stage 101 and the selection stage 102. The input branches 103a, 103b, 103c, 103d and 103e are here formed by respective output PMOS transistors 118a, 118b, 118c, 118d and 118e. A first and a second output PMOS transistor 118a, 118b are comprised in the control stage 101 and a third to a fifth output PMOS transistor 118c, 118e are comprised in the selection stage 102.

In particular, the input PMOS transistor 117 is coupled to the bit line BLᵢ through a decoupling NMOS transistor 114 which is comprised in the control stage 101 and has the gate connected to the biasing circuit 18 to receive the biasing voltage Vr, the drain coupled to the bit line BLᵢ to receive the bit line current I_{BL,i} and the source coupled to the input PMOS transistor 117. In fact, the decoupling NMOS transistor 114 allows the voltage on the bit line BLᵢ to be kept constant. Nonetheless, the decoupling NMOS transistor 114 may be replaced by any known-type circuit block that operates in a similar manner.

The sources of the PMOS transistors 117, 118a-118e are coupled to respective supply nodes 120, here to a supply voltage V_{DD}, while the gate of the input PMOS transistor 117 is coupled to each of the gates of the output PMOS transistors 118a-118e and to the drain of the input PMOS transistor 117. The drain of the first output PMOS transistor 118a is coupled, in particular here it is directly connected, to a first control input node 104a of the control stage 101; the drain of the second output PMOS transistor 118b is coupled, in particular here it is directly connected, to a second control input node 104b of the control stage 101; the drain of the third output PMOS transistor 118c is coupled, in particular here it is directly connected, to a selection common node 116 (hereinafter also referred to as input node 116 of the integration stage 110); the drain of the fourth output PMOS transistor 118d is coupled, in particular here it is directly connected, to a first selection switch 105a of the selection stage 102, which is interposed in the second selection input branch 103d between the fourth output PMOS transistor 118d and the selection common node 116; and the drain of the fifth output PMOS transistor 118e is coupled, in particular here it is directly connected, to a second selection switch 105b of the selection stage 102, which is interposed in the third selection input branch 103e between the fifth output PMOS transistor 118e and the selection common node 116.

Consequently and as better described below, the first control input node 104a receives the main control mirrored current k₁·I_{BL,i}, the second control input node 104b receives the control mirrored current k₁·I_{BL,i}, the selection common node 116 receives at least the first selection mirrored current k₂·I_{BL,i}, the first selection switch 105a receives the second selection mirrored current k₃·I_{BL,i} and the second selection switch 105b receives the third selection mirrored current k₄·I_{BL,i}.

The control stage 101 further comprises a secondary current mirror 144 which mirrors a biasing current I_{bias} in the first control input node 104a and in the second control input node 104b of the control stage 101, on the opposite side with respect to the main current mirror 115. In other words, the secondary current mirror 144 mirrors the biasing current I_{bias} in a first output branch 149a, coupled to the first control input node 104a and extending on the opposite side of the latter with respect to the main current mirror 115, and in a second output branch 149b, coupled to the second control input node 104b and extending on the opposite side of the latter with respect to the main current mirror 115.

For example, the biasing current I_{bias} is generated by a current generator 148, of a per se known type. The current generator 148 may be external to the digital detector 16 or may be internal thereto and, for example, may be provided through a bandgap circuit.

The secondary current mirror 144 has a respective mirror ratio for each of the output branches 149a and 149b considered. In particular, the secondary current mirror 144 has a first secondary control mirror ratio 1:p₁ for the first output branch 149a and has a second secondary control mirror ratio 1:p₂ for the second control input branch 103b. The first and the second secondary control mirror ratios 1:p₁, 1:p₂ are different from each other and are, usually, also different from the main control mirror ratio 1:k₁.

In detail, the first secondary control mirror ratio 1:p₁ has a mirroring coefficient p₁ which is greater than (in particular, double) the mirroring coefficient p₂ of the second secondary control mirror ratio 1:p₂. For example, p₁=4 and p₂=2.

In this manner, a first secondary control mirrored current p₁·I_{bias} flows through the first output branch 149a and a second secondary control mirrored current p₂·I_{bias} flows through the second output branch 149b. The first and the second secondary control mirrored currents p₁·I_{bias} and p₂·I_{bias} are different from each other and in particular p₁·I_{bias}>p₂·I_{bias} since p₁>p₂ has been considered. In the example considered here wherein p₁>1 and p₂>1, the first and the second secondary control mirrored currents p₁·I_{bias} and p₂·I_{bias} are greater than the biasing current I_{bias}.

In the embodiment exemplarily considered herein, the first secondary control mirrored current p₁·I_{bias} is equal to four times the biasing current I_{bias} since p₁=4, and the second secondary control mirrored current p₂·I_{bias} is equal to double the biasing current I_{bias} since p₂=2.

Conversely, in case the biasing current I_{bias} is relatively high, p₁<1 and p₂<1 may be chosen (e.g., p₁=1/2 and p₂=1/4) in such a way as to maintain the same values of the first and the second secondary control mirrored currents p₁·I_{bias} and p₂·I_{bias}.

In detail, the secondary current mirror 144 has a first branch, here formed by a respective input NMOS transistor 173, coupled to the current generator 148, and a plurality of second branches in parallel with each other, i.e., the first and the second output branches 149a, 149b. The output branches 149a and 149b are here formed by respective output NMOS transistors 174a and 174b (in detail, a first and a second output NMOS transistor 174a and 174b, respectively).

The sources of the NMOS transistors 173, 174a and 174b are coupled to a reference, here ground, while the gate of the input NMOS transistor 173 is coupled to each of the gates of the output NMOS transistors 174a and 174b and to the drain of the input NMOS transistor 173. The drain of the first output NMOS transistor 174a is coupled, in particular here it is directly connected, to the first control input node 104a of the control stage 101 and the drain of the second output NMOS transistor 174b is coupled, in particular here it is directly connected, to the second control input node 104b of the control stage 101.

Consequently, the first control input node 104a also receives the first secondary control mirrored current p₁·I_{bias} and the second control input node 104b also receives the second secondary control mirrored current p₂·I_{bias}.

Consequently, the first control input node 104a goes to the supply voltage V_{DD} when the main control mirrored current k₁·I_{BL,i} is greater than the first secondary control mirrored current p₁·I_{bias} and, vice versa, it goes to the ground voltage when the main control mirrored current k₁·I_{BL,i} is smaller than the first secondary control mirrored current p₁·I_{bias}. Similarly, the second control input node 104b goes to the supply voltage V_{DD} when the main control mirrored current k₁·I_{BL,i} is greater than the second secondary control mirrored current p₂·I_{bias} and, vice versa, it goes to the ground voltage when the main control mirrored current k₁·I_{BL,i} is smaller than the second secondary control mirrored current p₂·I_{bias}.

The control stage 101 comprises a first and a second control inverter 106a and 106b and further comprises a first and a second control flip-flop 107a and 107b of D-type, respectively coupled to the first control input node 104a and the second control input node 104b through the first and the second control inverters 106a and 106b, respectively.

In detail, the first control inverter 106a and the first control flip-flop 107a extend in a further branch of the control stage 101 different from the first output branch 149a and from the first control input branch 103a and which shares therewith the first control input node 104a; similarly, the second control inverter 106b and the second control flip-flop 107b extend in a further branch of the control stage 101 different from the second output branch 149b and the second control input branch 103b and which shares therewith the second control input node 104b.

In particular, the control flip-flops 107a and 107b each have a clock input (CK-input), a data input (D-input), a reset input (R-input), and a Q-output.

The first control inverter 106a has an input directly connected to the first control input node 104a and has an output directly connected to the D-input of the first control flip-flop 107a.

The R-input of the first control flip-flop 107a receives a negated reset signal RESET_N, for example generated by the control circuit 31 and configured to reset the first control flip-flop 107a when necessary (e.g., after switching on the IMC device 10 and, more generally, whenever it is necessary to have a known starting value stored in the control flip-flop 107a, for example between two computations successive to each other).

The CK-input of the first control flip-flop 107a receives a negated clock signal CLK_N, better described below.

The Q̅-output of the first control flip-flop 107a is directly coupled to a first intermediate node 108a of the control stage 101.

The second control inverter 106b has an input directly connected to the second control input node 104b and has an output directly connected to the D-input of the second control flip-flop 107b.

The R-input of the second control flip-flop 107b receives the negated reset signal RESET_N (for any resets of the second control flip-flop 107b) and the CK-input of the second control flip-flop 107b receives the negated clock signal CLK_N.

The Q̅-output of the second control flip-flop 107b is directly coupled to a second intermediate node 108b of the control stage 101.

The first and the second control flip-flops 107a and 107b substantially convert the analog-domain information carried by the voltage at which, respectively, the first and the second control input nodes 104a and 104b are into digital-domain information. In other words, the Q-output of the first control flip-flop 107a assumes a high logic value (e.g., ‘1’) when the first control input node 104a is at the supply voltage V_{DD} and assumes a low logic value (e.g., ‘0’) when the first control input node 104a is at ground voltage and, similarly, the Q̅-output of the second control flip-flop 107b assumes a high logic value (e.g., ‘1’) when the second control input node 104b is at the supply voltage V_{DD} and assumes a low logic value (e.g., ‘0’) when the second control input node 104b is at ground voltage.

In particular, the switching of the control flip-flops 107a and 107b occurs at the rising edge of the negated clock signal CLK_N, in order to synchronize the selection stage 102 and the charge counter stage 111 with each other, as better described hereinbelow.

The control stage 101 further comprises a set of control logic gates 109 coupled to the Q̅-outputs of the first and the second control flip-flops 107a and 107b and to the first and the second selection switches 105a and 105b and configured to generate, on the basis of the Q̅-outputs, a plurality of control signals S_{control,1}-S_{control,3} (in detail, a first to a third control signal S_{control,1}-S_{control,3} and a first negated control signal S̅_{control,1}) for controlling the selection switches 105a and 105b and the charge counter stage 111.

Hereinafter, for simplicity of notation, reference is made to the first output Q̅₁ to indicate the Q̅-output of the first control flip-flop 107a and to the second output Q̅₂ to indicate the Q̅-output of the second control flip-flop 107b.

The set of control logic gates 109 implements the following logic table:

| Q̅₁ | Q̅₂ | S_{control, 1} | S_{control, 2} | S_{control, 3} |
|---|---|---|---|---|
| 1 | 1 | 1 | 0 | 0 |
| 0 | 1 | 0 | 1 | 0 |
| 0 | 0 | 0 | 0 | 1 |

According to an exemplary embodiment, the set of control logic gates 109 comprises a non-inverting control buffer 109a, a first control inverter 109b, a control NOR gate 109c and a second control inverter 109d.

The non-inverting control buffer 109a is a non-inverting buffer which has an input directly connected to the first output Q̅₁ and which, in response to the first output Q̅₁, generates at output the first control signal S_{control,1} equal to the first output Q̅₁.

The first control inverter 109b is a logic inverter which has an input directly connected to the output of the non-inverting control buffer 109a and which, in response to the first control signal S_{control,1}, generates at output the first negated control signal S̅_{control,1} equal to the negation of the first control signal S_{control,1}.

The control NOR gate 109c is a NOR-type logic gate which has a first input of non-negated type and directly connected to the first output Q̅₁ and a second input of negated type and directly connected to the second output Q̅₂. In response to the first and the second outputs Q̅₁ and Q̅₂, the control NOR gate 109c generates at output the second control signal S_{control,2} which assumes a high logic value when the first output Q̅₁ has a low logic value and the second output Q̅₂ has a high logic value, and assumes a low logic value both when the first and the second outputs Q̅₁ and Q̅₂ have a high logic value and when the first and the second outputs Q̅₁ and Q̅₂ have a low logic value.

The second control inverter 109d is a logic inverter which has an input directly connected to the second output Q̅₂ and which, in response to the second output Q̅₂, generates at output the third control signal S_{control,3} equal to the negation of the second output Q̅₂.

With reference to the selection stage 102, the selection switches 105a and 105b are controlled on the basis of the control signals (in detail, as a function of the first negated control signal S̅_{control,1} and the third control signal S_{control,3}).

In particular, the first selection switch 105a is selectively controllable in a closed (conduction) state or in an open (inhibition) state as a function of the first negated control signal S̅_{control,1} and the second selection switch 105a is selectively controllable in a respective closed (conduction) state or in a respective open (inhibition) state as a function of the third control signal S_{control,3}.

For example, when the first negated control signal S̅_{control,1} assumes the logic high value the first selection switch 105a is in the closed state and allows the second selection mirrored current k₃·I_{BL,i} to flow through the second selection input branch 103d up to reaching the selection common node 116, while when it assumes the low logic value the first selection switch 105a is in the open state and prevents the second selection mirrored current k₃·I_{BL,i} from flowing through the second selection input branch 103d up to reaching the selection common node 116; similarly, when the third control signal S_{control,3} assumes the high logic value the second selection switch 105b is in the closed state and allows the third selection mirrored current k₄·I_{BL,i} to flow through the third selection input branch 103e up to reaching the selection common node 116, while when it assumes the low logic value the second selection switch 105b is in the open state and prevents the third selection mirrored current k₄·I_{BL,i} from flowing through the third selection input branch 103e up to reaching the selection common node 116.

Consequently, the selection common node 116 collects a total selection current I_{sel,tot} which depends on the state of the selection switches 105a, 105b and which flows towards the integration stage 110. The states of the selection switches 105a, 105b therefore determine at each time a respective mutual combination of the selection mirrored currents, which corresponds to the total selection current I_{sel,tot}.

The total selection current I_{sel,tot} is lower than, or alternatively equal to, the bit line current I_{BL,i}; in particular, I_{sel,tot}<I_{BL,i}.

In detail, the total selection current I_{sel,tot} decreases with respect to the bit line current I_{BL,i} correspondingly (in particular, proportionally) to how much the bit line current I_{BL,i} increases. In other words, the more the bit line current I_{BL,i} grows, the more the total selection current I_{sel,tot} decreases with respect to the bit line current I_{BL,i} so as not to increase correspondingly to the increase of the bit line current I_{BL,i}.

In the embodiment considered here, the bit line current I_{BL,i} may have a value which at any time is comprised in one of three current variation intervals, consecutive to each other and with increasing values (better described hereinbelow). As a function of this comparison of the bit line current I_{BL,i} with the current variation intervals, the total selection current I_{sel,tot} is selected correspondingly so as to be as different from the bit line current I_{BL,i} as the greater the bit line current I_{BL,i} (i.e., the difference between the bit line current I_{BL,i} and the total selection current I_{sel,tot} is minimum when the bit line current I_{BL,i} belongs to the first current variation interval, minimum, and is maximum when the bit line current I_{BL,i} belongs to the third current variation interval, maximum).

In particular, the total selection current I_{sel,tot} comprises at least the first selection mirrored current k₂·I_{BL,i} because the selection common node 116 is directly connected to the drain of the third output PMOS transistor 118c.

Furthermore, when the first negated control signal S̅_{control,1} assumes the high logic value, the total selection current I_{sel,tot} also comprises the second selection mirrored current k₃·I_{BL,i}.

Furthermore, when the third control signal S_{control,3} assumes the high logic value, the total selection current I_{sel,tot} also comprises the third selection mirrored current k₄·I_{BL,i}.

In other words, in the embodiment considered here the following cases may arise:
if k₁·I_{BL,i}>p₁·I_{bias} (i.e., in the example considered, if I_{BL,i}>4·I_{bias} and therefore one is in the third current variation interval), then Q̅₁=‘1’ and Q̅₂=‘1’, thus S_{control,1}=‘1’, S_{control,2}=‘0’, S_{control,3}=‘0’, S̅_{control,1}=‘0’ and therefore I_{sel,tot}=k₂·I_{BL,i} (i.e., in the example considered, I_{sel,tot}=I_{BL,i}/⁴);
if p₂·I_{bias}<k₁·I_{BL,i}<p₁·I_{bias} (i.e., in the example considered, if 2·I_{bias}<I_{BL,i}<4·I_{bias} and therefore one is in the second current variation interval), then Q̅₁=‘0’ and Q̅₂=‘1’, thus S_{control,1}=‘0’, S_{control,2}=‘1’, S_{control,3}=‘0’, S_{control,1}=‘1’ and therefore I_{sel,tot}=k₂·I_{BL,i}+k₃·I_{BL,i} (i.e., in the example considered, I_{sel,tot}=I_{BL,i}/2);
if k₁·I_{BL,i}<p₂·I_{bias} (i.e., in the example considered, if I_{BL,i}<2·I_{bias} and therefore one is in the first current variation interval), then Q̅₁=‘0’ and Q̅₂=‘0’, thus S_{control,1}=‘0’, S_{control,2}=‘0’, S_{control,3}=‘1’, S_{control,1}=‘1’ and therefore I_{sel,tot}=k₂·I_{BL,i}+k₃·I_{BL,i}+k₄·I_{BL,i} (i.e., in the example considered, I_{sel,tot}=I_{BL,i}).

Consequently, even when the value of the current I_{BL,i} which flows through the respective bit line BLᵢ is high (e.g., it is comprised in the third current variation interval), the total selection current I_{sel,tot} which arrives at the input of the integration stage 110 remains lower than the current I_{BL,i} and in general relatively small.

In fact, the comparison based on the three current variation intervals (k₁·I_{BL,i}>p₁·I_{bias}, p₂·I_{bias}<k₁·I_{BL,i}<p₁·I_{bias} or k₁·I_{BL,i}<p₂·I_{bias}) implemented by the control stage 101 and the corresponding selection by the selection stage 102 of the total selection current I_{sel,tot} to be received by the integration stage 110 (chosen correspondingly in three different manners, i.e., I_{sel,tot}=k₂·I_{BL,i}+k₃·I_{BL,i}+k₄·I_{BL,i}, I_{sel,tot}=k₂·I_{BL,i}+k₃·I_{BL,i} or I_{sel,tot}=k₂·I_{BL,i}) allows the total selection current I_{sel,tot}, which the integration stage 110 needs to sample even in case of high current I_{BL,I}, to be maintained low.

In detail, when the main control mirrored current k₁·I_{BL,i} is of reduced intensity (i.e., it is lower than the second secondary control mirrored current p₂·I_{bias}), the total selection current I_{sel,tot} which arrives at the input of the integration stage 110 is also relatively small (I_{sel,tot}=k₂·I_{BL,i}+k₃·I_{BL,i}+k₄·I_{BL,i} and i.e., it is lower than the second secondary control mirrored current p₂·I_{bias}); when the main control mirrored current k₁·I_{BL,i} is of medium intensity (i.e., it is comprised between the first and the second secondary control mirrored current p₁·I_{bias} and p₂·I_{bias}), the total selection current I_{sel,tot} which arrives at the input of the integration stage 110 is however relatively small (I_{sel,tot}=k₂·I_{BL,i}+k₃·I_{BL,i} and i.e., it is lower than the second secondary control mirrored current p₂·I_{bias}); and when the main control mirrored current k₁·I_{BL,i} is of high intensity (i.e., it is higher than the first secondary control mirrored current p₁·I_{bias}), the total selection current I_{sel,tot} which arrives at the input of the integration stage 110 is however relatively small (I_{sel,tot}=k₂·I_{BL,i} and i.e., it is lower than the second secondary control mirrored current p₂·I_{bias}). In other words, in any of the three cases the total selection current I_{sel,tot} which arrives at the input of the integration stage 110 is relatively small.

Furthermore, the presence of the first and the second control flip-flops 107a and 107b causes the synchronous switching of the set of control logic gates 109, which occurs in particular in the rising edges of the negated clock signal CLK_N. This allows synchronous control of both the selection switches 105a and 105b and the charge counter stage 111 and therefore prevents the total selection current I_{sel,tot} from varying while integrated and the charge counter stage 111 from incorrectly measuring the total selection current I_{sel,tot} previously integrated. In other words, this optimizes the operation of the digital detector 16 by preventing calculation errors of the IMC device 10.

With reference now to the integration stage 110, it allows the total selection current I_{sel,tot} to be sampled generating corresponding charge packets which are then counted by the charge counter stage 111.

The integration stage 110 comprises a first integration circuit 121, a second integration circuit 122 and a switching circuit 123 coupled between the first and the second integration circuits 121, 122.

The first and the second integration circuits 121, 122 are coupled to the input node 116 (i.e., to the selection common node 116) so as to receive the total selection current I_{sel,tot}.

The first integration circuit 121 comprises a first inverter 124 having an output 125, a capacitor 127 of capacitance C_{A} coupled to the output 125 of the first inverter 124, and a second inverter 128 whose input is coupled to the output 125 of the first inverter 124.

The first inverter 124 has a supply node coupled to the input node 116 of the integration stage 110 and receives at input a first control signal IN_{A}.

In practice, the first inverter 124 is biased by the total selection current I_{sel,tot}.

The capacitor 127 has a first terminal coupled to the output node 125 of the first inverter 124 and a second terminal coupled to a reference node, here to ground.

The output node 125 of the first inverter 124 is at a first integration voltage V_{A} which drops across the capacitor 127.

The second inverter 128 has a first sampling threshold, hereinafter referred to as first threshold Vₜₕ₁, receives at input the first integration voltage V_{A} and provides at output a first switch signal S1 as a function of the first threshold Vₜₕ₁ and the first integration voltage V_{A}.

In detail, the first switch signal S1 is a logic signal having a high logic value when the first integration voltage V_{A} is lower than the first threshold Vₜₕ₁, and a low logic value when the first integration voltage V_{A} is higher than the first threshold Vₜₕ₁.

The second integration circuit 122 comprises a first inverter 130 having an output 131, a capacitor 132 of capacitance CB coupled to the output 131 of the first inverter 130, and a second inverter 133 whose input is coupled to the output 131 of the first inverter 130.

The first inverter 130 has a supply node coupled to the input node 116 of the integration stage 110 and receives at input a second control signal IN_{B}.

In practice, the first inverter 130 is biased by the total selection current I_{sel,tot}.

The capacitor 132 has a first terminal coupled to the output node 131 of the first inverter 130 and a second terminal coupled to a reference node, here to ground.

The output node 131 of the first inverter 130 is at a second integration voltage V_{B} which drops across the capacitor 131.

The second inverter 133 has a second sampling threshold Vₜₕ₂, hereinafter referred to as second threshold Vₜₕ₂, receives at input the second integration voltage V_{B} and provides at output a second switch signal S2 as a function of the second threshold Vₜₕ₂ and the second integration voltage V_{B}.

In detail, the second switch signal S2 is a logic signal having a high logic value when the second integration voltage V_{B} is lower than the second threshold Vₜₕ₂, and a low logic value when the second integration voltage V_{B} is higher than the second threshold Vₜₕ₂.

In this embodiment, the first threshold Vₜₕ₁ is equal to the second threshold Vₜₕ₂; however, the first threshold Vₜₕ₁ may be different from the second threshold Vₜₕ₂, according to the specific application.

The switching circuit 123 is a latch formed by two inverters 135, 136 arranged in a ring configuration, a first switch 137 controlled by the first switch signal S1 and a second switch 138 controlled by the second switch signal S2.

The switching circuit 123 has a first node 140 coupled to the input of the inverter 136 and to the output of the inverter 135, and a second node 141 coupled to the output of the inverter 136 and to the input of the inverter 135.

The first node 140 provides the first control signal IN_{A}. The second node 141 provides the second control signal IN_{B}.

The first switch 137 is coupled between the first node 140 and a node at a voltage V′_{DD}, the second switch 138 is coupled between the second node 141 and the node at the voltage V′_{DD}.

The voltage V′_{DD} may be equal to or different from the supply voltage V_{DD} of the supply node 120. For example, if the voltage V′_{DD} is different from, in particular lower than, the supply voltage V_{DD}, the digital detector 16 may comprise a voltage scaling circuit, for example a transistor, here not shown, whose source and drain terminals are coupled between the supply node 120 and the input node 116 of the integration stage 110.

In this embodiment, the switching circuit 123 also receives the enable signal EN, which controls the activation of the switching circuit 123. For example, the enable signal EN may be used to maintain the switching circuit 123 off when is not in use, thereby allowing the energy consumption to be optimized. Furthermore, the enable signal EN may be used to set the switching circuit 123 to a defined state, for example when the IMC device 10 is switched on.

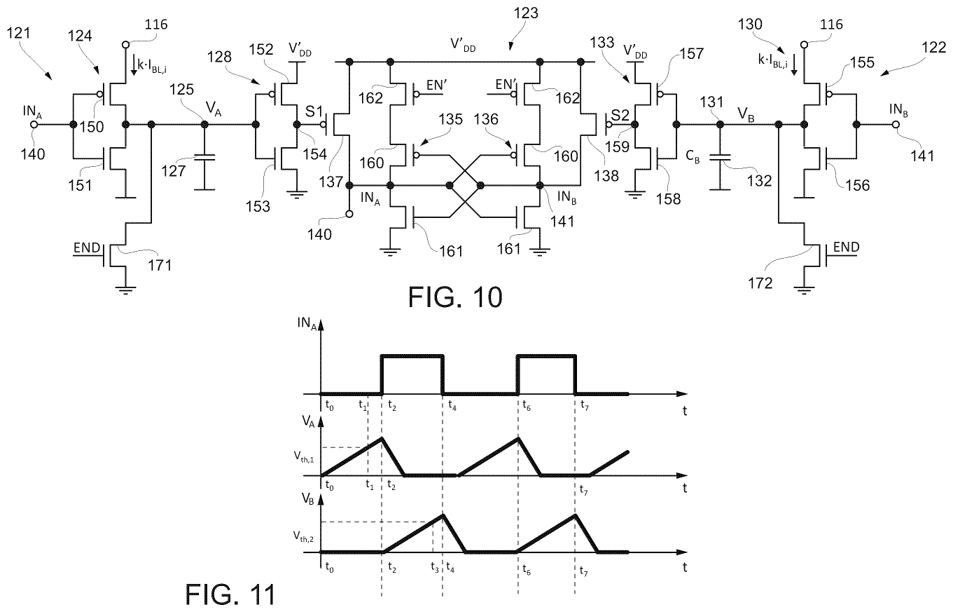

As better described hereinbelow with reference to FIGS. 10 and 11, each switching of the switching circuit 123 corresponds to the detection of a respective charge packet, measured in response to the total selection current I_{sel,tot}.

With reference now to the charge counter stage 111, it is implemented through a “ripple counter”, in particular with D-type flip-flops.

The charge counter stage 111 is coupled to the integration stage 110 to count the charge packets measured by the latter, and is coupled to the control stage 101 to be controlled on the basis of the control signals (in detail, as a function of the first to the third control signal S_{control,1}-S_{control,3}) in such a way as to compensate, in the count of the charge packets, the three different options for generating the total selection current I_{sel,tot} and therefore the corresponding values that it may assume and the different weight that the charge packets may have.

In fact, currents I_{BL,i} which flow through the respective bit line BLᵢ and which are also substantially different in intensity (e.g., which belong to different current variation intervals) are converted by the control stage 101 and by the selection stage 102 into corresponding total selection currents I_{sel,tot} which have reduced intensity. However, counting charge packets measured in response to currents I_{BL,i} different from each other in the same manner would lead to an incorrect final count, due to the different weight that the charge packets actually have.

Conversely, assigning a different weight to the charge packets as a function of the total selection current I_{sel,tot} on which their measurement is based avoids this drawback.

In other words, the charge counter stage 111 counts the charge packets taking into account the degree of scaling of the total selection current I_{sel,tot} with respect to the current I_{BL,i} of the bit line BLᵢ, operated by the selection stage 102. This is done by controlling the charge counter stage 111 based on the control signals.

In detail, the charge counter stage 111 is coupled to the first node 140 of the switching circuit 123.

The charge counter stage 111 has a counter comprising a count inverter 145, a plurality of count selectors 175 (one for each current variation interval, therefore three in this case) and a plurality of count flip-flops 147 (in particular of D-type and including at least a number of count flip-flops 147 equal to the number of current variation intervals, therefore three in this case).

The count inverter 145 is a logic inverter that has an input coupled to the first node 140 of the integration stage 110 and an output configured to generate the previously described negated clock signal CLK_N.

The count selectors 175 are multiplexers, in particular of 2:1-type (i.e., each having a first input 175a, a second input 175b and an output 175c).

Each count selector 175 further has a control input 175d coupled to the control stage 101 to receive one of the control signals S_{control,1}-S_{control,3}.

The count selectors 175 are controlled through the control signals S_{control,1}-S_{control,3}, i.e., they each selectively connect the output 175c with one of the first input 175a and the second input 175b as a function of the respective control signal. For example, each count selector 175 selectively connects the output 175c to the first input 175a when the respective control signal received at the control input 175d assumes the logic high value (“1”) and selectively connects the output 175c to the second input 175b when the respective control signal received at the control input 175d assumes the low logic value (“0”).

The count selectors 175 are connected, in particular directly connected, to respective count flip-flops 147 and, in detail, to the first three count flip-flops 147.

In particular, a first count selector 175.1, a second count selector 175.2 and a third count selector 175.3 are present.

The first input 175a of each count selector 175 is coupled, in particular directly connected, to the output of the count inverter 145 and therefore receives the negated clock signal CLK_N.

Furthermore, the second input 175b of the first count selector 175.1 receives a predefined logic signal, in particular a high logic signal (‘1’). For example, the predefined logic signal is generated by the control circuit 31.

The control input 175d of the first count selector 175.1 is coupled, in particular directly connected, to the output of the second control inverter 109d of the control stage 101 and therefore receives the third control signal S_{control,3}.

The control input 175d of the second count selector 175.2 is coupled, in particular directly connected, to the output of the control NOR gate 109c of the control stage 101 and therefore receives the second control signal S_{control,2}.

The control input 175d of the third count selector 175.3 is coupled, in particular directly connected, to the output of the non-inverting control buffer 109a of the control stage 101 and therefore receives the first control signal S_{control,1}.

In the embodiment exemplarily shown in FIG. 9, a first count flip-flop 147.1 to a fourth count flip-flop 147.4 and a last count flip-flop 147.F are shown, where F is the number of bits of the output signal yᵢ.

In practice, the counter of the charge counter stage 111 has F count flip-flops 147.

The count flip-flops 147 are cascaded with each other, sequentially from the first count flip-flop 147.1 to the last count flip-flop 147.F.

The count flip-flops 147 each have a clock input (CK-input), a data input (D-input), a reset input (R-input), a Q-output (or first output) and a Q-output (or second output).

The R-inputs of the count flip-flops 147 receive the negated reset signal RESET_N, for example generated by the control circuit 31 and configured to reset the count flip-flops 147 when necessary (e.g., after switching on the IMC device 10 and, more generally, whenever it is necessary to have known starting values stored in the count flip-flops 147, for example between two successive computations).

The CK-inputs of the first, the second and the third count flip-flops 147.1-147.3 are connected, in particular directly coupled, to the outputs 175c of the respective count selectors 175.1-175.3 so as to receive flip-flop input signals generated by count selectors 175.1-175.3. In other words, the CK-input of the first count flip-flop 147.1 is coupled to the output 175c of the first count selector 175.1, the CK-input of the second count flip-flop 147.2 is coupled to the output 175c of the second count selector 175.2, the CK-input of the third count flip-flop 147.3 is coupled to the output 175c of the third count selector 175.3.

Furthermore, the CK-inputs of the remaining count flip-flops 147.4-147.F (i.e., those except for the first, the second and the third count flip-flops 147.1-147.3) are connected, in particular directly coupled, each to the Q-output of the immediately preceding count flip-flop. For example, the CK-input of the fourth count flip-flop 147.4 is coupled to the Q-output of the third count flip-flop 147.3, the CK-input of the fifth count flip-flop 147.5 is coupled to the Q-output of the fourth count flip-flop 147.4, etc.

The Q-output of each count flip-flop 147 is fed back to the D-input of the same count flip-flop 147. In other words, the Q-output of the first count flip-flop 147.1 is directly connected to the D-input of the first count flip-flop 147.1 and this applies, mutatis mutandis, to all the successive count flip-flops 147.

The Q-output of each count flip-flop 147 is a respective bit yᵢ of the output signal yᵢ. In detail, the Q-output of the first flip-flop 147.2 is the first bit yᵢ(1) (i.e., the least significant bit) of the output signal yᵢ, the Q-output of the second flip-flop 147.2 is the second bit yᵢ(2) of the output signal yᵢ, etc. This applies, mutatis mutandis, to all the successive count flip-flops 147. Consequently, the Q-output of the last count flip-flop 147.F is the most significant bit yᵢ(F) of the output signal yᵢ.

With reference to FIG. 10, the structure of the integration stage 110 is now described in more detail.

The first inverter 124 of the first integration circuit 121 is a CMOS inverter formed by the series circuit of a PMOS transistor 150 and an NMOS transistor 151, mutually coupled to the output node 125. The PMOS and NMOS transistors 150, 151 receive the first control signal IN_{A} at the respective gate terminals.

The source of the PMOS transistor 150 is coupled to the input node 116 of the integration stage 110.

The second inverter 128 of the first integration circuit 121 is a CMOS inverter formed by the series circuit of a PMOS transistor 152 and an NMOS transistor 153, mutually coupled to a node 154 providing the first switch signal S1.

The first threshold Vₜₕ₁ of the second inverter 128 is the switching threshold of the second inverter 128, and therefore depends on the properties, for example on the threshold or on-state resistance, of the PMOS and NMOS transistors 152, 153. In practice, the switching threshold may be the input voltage for which the output of the inverter has a high logic value or the input voltage for which the output of the inverter has a low logic value.

For example, the switching threshold of the second inverter 128 may be defined as the operating point at which the respective input voltage, i.e., the first integration voltage V_{A}, is equal to the respective output voltage, i.e., the first switch signal S1.

The first inverter 130 of the second integration circuit 122 is a CMOS inverter formed by the series circuit of a PMOS transistor 155 and an NMOS transistor 156, mutually coupled to the output node 131. The PMOS and NMOS transistors 155, 156 receive the second control signal IN_{B} at the respective gate terminals.

The source of the PMOS transistor 155 is coupled to the input node 116 of the integration stage 110.

The second inverter 133 of the second integration circuit 122 is a CMOS inverter formed by the series circuit of a PMOS transistor 157 and an NMOS transistor 158, mutually coupled to a node 159 providing the second switch signal S2.

The second threshold Vₜₕ₂ of the second inverter 133 is the switching threshold of the second inverter 133, i.e., it depends on the properties of the PMOS and NMOS transistors 157, 158. For example, the switching threshold depends on the gate-source voltage which allows a current to flow through the source-drain path of the PMOS and NMOS transistors 157, 158.

As shown in the detailed implementation of FIG. 10, the first and the second inverters 135, 136 of the switching circuit 123 are cross-coupled CMOS inverters each comprising a respective PMOS transistor 160 and a respective NMOS transistor 161 mutually coupled in series between a supply node, here at the voltage V′_{DD}, and ground.

Furthermore, the first and the second inverters 135, 136 of the switching circuit 123 each also comprise a respective enable switch, here a PMOS transistor 162, which is coupled between the supply node at the voltage V′_{DD} and the PMOS transistor 160 of the respective inverter.

The PMOS transistors 162 are controlled by the enable signal EN.

In use, the total selection current I_{sel,tot} is mirrored in the integration stage 110 of the respective digital detector 16.

FIG. 11 shows an example of the trend over time of the first control signal IN_{A}, of the first integration voltage V_{A} and of the second integration voltage V_{B} of the digital detector 16 of FIG. 9.

For t₀<t<t₁, the first integration voltage V_{A} is lower than the first threshold V_{th,1}.

Consequently, the PMOS transistor 152 of the second inverter 128 is on and the NMOS transistor 153 of the second inverter 128 is off. Therefore, the first switch signal S1 (here not shown) has a high value and the first switch 137 is open. The first control signal IN_{A} has a low value.

As a result, with reference to the first inverter 124 of the first integration circuit 121, for t₀<t<t₁, the PMOS transistor 150 is on and the NMOS transistor 151 is off.

At the same time, for t₀<t<t₁, the second control signal IN_{B} has the high value. Therefore, with reference to the first inverter 130 of the second integration circuit 122, for t₀<t<t₁, the PMOS transistor 155 is off and the NMOS transistor 156 is on.

Consequently, the total selection current I_{sel,tot} flows, from the input node 116, only through the first inverter 124 of the first integration circuit 121 and not through the first inverter 130 of the second integration circuit 122.

In detail, the total selection current I_{sel,tot} flows through the PMOS transistor 150 and charges the capacitor 127. The first integration voltage V_{A} thus increases over time for t₀<t<t₁.

In detail, in the example of FIG. 11, the first integration voltage V_{A} increases linearly over time for t₀<t<t₁; however, the trend of the first integration voltage V_{A} depends on the specific trend of the total selection current I_{sel,tot} in the time interval t₀<t<t₁.

When the first integration voltage V_{A} becomes equal to the first threshold voltage V_{th,1}, the NMOS transistor 153 of the second inverter 128 switches on and the PMOS transistor 152 switches off.

In this embodiment, the first control signal IN_{A} assumes a high value in a time instant t₂.

The time delay between the times t₁ and t₂ may correspond, for example, to the propagation delay of the second inverter 128 of the first integration circuit 121 and/or to the switching time of the first switch 137.

For t₁<t<t₂, the total selection current I_{sel,tot} continues to charge the capacitor 127; consequently, the first integration voltage V_{A} increases up to a maximum value (time t₂).

At time instant t₂, when the first control signal IN_{A} assumes a high value, the second control signal IN_{B} (here not shown) assumes a low value (the inverter 136 of the switching circuit 123 receives at input the first control signal IN_{A}).

While the first control signal IN_{A} has a high value, the PMOS transistor 150 and the NMOS transistor 151 of the first inverter 124 of the first integration circuit 121 are, respectively, off and on. At the same time, while the second control signal IN_{B} has a low value, the PMOS transistor 155 and the NMOS transistor 156 of the first inverter 130 of the second integration circuit 122 are, respectively, on and off.

Therefore, for t>t₂, the total selection current I_{sel,tot} flows, from the input node 116, only through the first inverter 130 of the second integration circuit 122 and not through the first inverter 124 of the first integration circuit 121.

In detail, the total selection current I_{sel,tot} flows through the PMOS transistor 155 and charges the capacitor 132 of the second integration circuit 122. The second integration voltage V_{B} thus increases over time from time instant t₂.

In detail, in the example of FIG. 11, the second integration voltage V_{B} increases linearly over time for t>t₂; however, the trend of the second integration voltage V_{B} depends on the specific trend of the total selection current I_{sel,tot}.

While the first control signal IN_{A} has a high value, the capacitor 127 of the first integration circuit 121 discharges through the NMOS transistor 151 of the first inverter 124.

The first integration voltage V_{A} thus decreases to zero.

When the second integration voltage V_{B} becomes equal to the second threshold voltage V_{th,2} (time instant t₃), the NMOS transistor 158 of the second inverter 133 switches on and the PMOS transistor 157 switches off.

Consequently, at a time instant t₄, the second control signal IN_{B} assumes a high value, similarly to what has been discussed above for the first control signal IN_{A} at time instant t₂.

In detail, in response to the second integration voltage V_{B} reaching the second threshold V_{th,2}, the second switch signal S2 switches to the low value and the second switch 138 closes, so that the second node 141 is at the voltage V′_{DD} and, consequently, the second control signal IN_{B} assumes a high value.

The time delay between the times t₃ and t₄ may correspond, for example, to the propagation delay of the second inverter 133 of the second integration circuit 122 and/or to the switching time of the second switch 138.

For t₃<t<t₄, the total selection current I_{sel,tot} continues to charge the capacitor 132 of the second integration circuit 122; consequently, the second integration voltage V_{B} increases up to a maximum value (time t₄).

For t₂<t<t₄, the switching circuit 123 maintains the first control signal IN_{A} to the high value and the second control signal IN_{B} to the low value.

At time instant t₄, the first control signal IN_{A} assumes again a low value, in response to the second control signal IN_{B} assuming the high value.

In response to the first control signal IN_{A} assuming the low value, the total selection current I_{sel,tot} returns to charge the capacitor 127 of the first integration circuit 121 up to a time instant t₆, similarly to what has been discussed for t₁<t<t₂.

Consequently, from time instant t₆ to time instant t₇, the total selection current I_{sel,tot} charges the capacitor 132 of the second integration circuit 122 up to a time instant t₇, similarly to what has been discussed for t₂<t<t₄.

Again, with reference to FIG. 9, the charge counter stage 111 counts the number of switching events of the first control signal IN_{A}, in particular in this embodiment it counts the number of rising edges of the first control signal IN_{A}.

In practice, the digital detectors 16 each measure the bit line current I_{BL,i} of the respective bit line BLᵢ performing a number of successive sampling iterations of total selection currents I_{sel,tot} obtained in response to the respective bit line currents I_{BL,i}.

In each sampling iteration, for example with reference to a sampling iteration wherein the total selection current I_{sel,tot} flows through the first integration circuit 121, the integration stage 110 generates the first integration voltage V_{A} as the time integral of the total selection current I_{sel,tot}, compares the first integration voltage V_{A} with the first threshold V_{th,1} and, in response to the first integration voltage V_{A} reaching the first threshold V_{th,1}, resets the first integration voltage V_{A}, in particular here by switching the first control signal IN_{A}. This event corresponds to the detection of a charge packet. The charge counter stage 111 thus updates the respective output signal yᵢ in response to the first integration voltage V_{A} reaching the first threshold V_{th,1}.

In other words, the digital detectors 16 each sample the respective total selection current I_{sel,tot} into a number of charge packets and counting said charge packets, wherein each charge packet corresponds to the charge accumulated on the capacitors 127, 132 which causes a switching of the second inverters 128, 133.

As a result, the capacitors 127, 132 may have a reduced capacitance if compared with a case in which the bit line current is integrated all at once on a single capacitor of capacitance Cₜₒₜ. In detail, the capacitance of the capacitors 127, 132 may be lower than the capacitance Cₜₒₜ by a factor ₂F, wherein F is the number of bits of the output signal yᵢ.

Therefore, the digital detectors 16 may have a small die area occupation and, consequently, the IMC device 10 may have low manufacturing costs.

Furthermore, the digital detectors 16 each begin to discretize the respective bit line current I_{BL,i} as the bit line current I_{BL,i} traverses the respective bit line BLᵢ. Therefore, the output signal yᵢ may be ready immediately after the end of a computation performed by the IMC device 10 or immediately after the stop of the respective bit line current I_{BL,i}.

For example, according to one embodiment, the digital detectors 16 may each sample the respective bit line current I_{BL,i} until the digital detectors 16 receive a stopping signal, for example from a user of the IMC device 10 or from the word line activation circuit 14, indicating the end of the computation performed by the IMC device 10.

Therefore, the digital detectors 16 may have a fast measurement time, thereby allowing the IMC device 10 to have a low computation time.

Furthermore, according to the illustrated embodiment, the switching circuit 123 disables the first integration circuit 121 and enables the second integration circuit 122, in response to the first integration signal V_{A} reaching the first threshold V_{th,1}, and enables the first integration circuit 121 and disables the second integration circuit 122, in response to the second integration signal V_{B} reaching the second threshold V_{th,2}.

This allows the total selection current I_{sel,tot} to be alternately sampled by the first integration circuit 121 and the second integration circuit 122, thereby allowing the total selection current I_{sel,tot} to charge the capacitor 127 while the capacitor 132 is discharging and to charge the capacitor 132 while the capacitor 127 is discharging. By doing so, no charge may be lost during sampling and the digital detector 16 may reach a high measurement accuracy of the bit line current I_{BL,i}.

Again with reference to FIG. 10, the integration stage 110 may further comprise a first and a second stopping switch, here a first and a second NMOS transistor 171, 172, which prevent the respective digital detector 16 from sampling the respective total selection current I_{sel,tot}.

In detail, the first and the second NMOS transistors 171, 172 have a drain terminal coupled to the output nodes 127, 131 of the first and, respectively, the second integration circuits 121, 122; and a source terminal coupled to a reference potential line, here ground. The first and the second NMOS transistors 171, 172 receive, at the respective gate terminals, the end-of-count signal END.

When the timer signal TM<L:1> becomes equal to the maximum count signal MAX_CNT<L:1>, the end-of-computation comparator 170 switches the end signal END to the high logic value, thereby switching on the first and the second NMOS transistors 171, 172 and short-circuiting to ground the output nodes 127, 131 of the first and the second integration circuits 121, 122.

Consequently, the first and the second integration circuits 121, 122 stop integrating the total selection current I_{sel,tot}.

In practice, the end-of-count signal END may be used to determine the end of the MAC calculation by the IMC device 10.

In practice, in the previously described embodiment, the integration stage 181 of the timer 45 has a circuit diagram equal to the circuit diagram of the integration stage 110 of any of the digital detectors 16.

As a result, the timer 45 generates the timer signal TM<L:1> from the oscillator current I_{OSC} in the same manner as any of the digital detectors 16 generates the output datum yᵢ from the respective total selection current I_{sel,tot}.

Furthermore, in this embodiment the first threshold V′ₜₕ₁ of the second inverter 200 of the timer 45 is equal to the first threshold Vani of the second inverter 128 of the digital detectors 16 and the second threshold V′ₜₕ₂ of the second inverter 205 of the timer 45 is equal to the second threshold Vₜₕ₂ of the second inverter 133 of the digital detectors 16.

Furthermore, the voltage V′_{DD} of the count portion 181 of the timer 45 may be equal to the voltage V′_{DD} of the integration stage 110 of the digital detector 16.

In use, the fact that the timer 45 generates the timer signal TM<L:1> from the oscillator current I_{OSC} in the same manner as the digital detectors 16 each generate the respective output datum yᵢ from the respective total selection current I_{sel,tot}, in particular the fact that the respective integration circuits 110, 181 have the same circuit diagram, allows a strong correlation between the timer signal TM<L:1> and the output data y₁, . . . , y_{M} to be obtained.

Therefore, global variations that may affect the IMC device 10, such as, for example, drifts of the supply voltages V_{DD}, V′_{DD} and/or temperature variations, are compensated by the timer 45 and by the digital detectors 16, without thereby affecting the accuracy of the MAC operation performed by the IMC device 10.

The IMC device 10 is controllable in use through a control method which in particular comprises the following steps: providing, by the word line activation circuit 14, the word line activation signals 21 to the memory cells 20; generating, by the biasing circuit 18, the biasing voltage Vr and applying the biasing voltage Vr to the bit lines BLᵢ; generating, by the control stage 101, the main control mirrored currents k₁·I_{BL,i} in response to the bit line current I_{BL,i}; comparing, by the control stage 101, the main control mirrored currents k₁·I_{BL,i} with the reference currents (i.e., with p₁·I_{bias}, etc.); generating, by the control stage 101, the control signals S_{control,1}-S_{control,3}, S̅_{control,1} indicative of said comparison; generating, by the selection stage 102, the total selection current I_{sel,tot} in response to the bit line current I_{BL,i} and as a function of the control signals S_{control,1}-S_{control,3}, S̅_{control,1}; sampling, by the integration stage 110, the total selection current I_{sel,tot}; and generating, by the charge counter stage 111 and as a function of the control signals S_{control,1}-S_{control,3}, S̅_{control,1}, the output signal Y in response to sampling the first total selection current I_{sel,tot}.

From an examination of the characteristics of the invention made according to the present invention the advantages that it affords are evident.

The IMC device 10 allows MAC operations to be performed in an optimized manner, with reduced times and with high accuracy.

In particular, the use of the digital detectors 16 as shown in FIG. 9 allows the integration stage 110 of each digital detector 16 to sample low currents (i.e., to sample the total selection current I_{sel,tot} in lieu of the bit line current I_{BL,i}) and therefore generates charge packets which have respective additional amounts of charge Q_{add} which are of reduced extent and above all approximately equal to each other. This allows the sampled charge packets to be substantially identical to each other and independent of the extent of the bit line current I_{BL,i} at the input of the digital detector 16 considered. Therefore, the measurement accuracy of the bit line current I_{BL,i} and in general the calculation precision of the IMC device 10, increases.

This is made possible through the comparison based on the different current variation intervals (exemplarily three, in the previously considered embodiment) to assess the intensity of the bit line current I_{BL,i}, and through the successive sampling of a fictitious current (i.e., the total selection current I_{sel,tot}) generated by the selection stage 102 as a function of the comparison result and therefore correlated to the extent of the bit line current I_{BL,i}.

In other words, by limiting the quantity of the input currents to the integration stage 110 it is possible to ensure that the latter operates in an operating region wherein its operating accuracy is less compromised by the additional amounts of charge Q_{add}. Consequently, it is possible to perform the entire measurement with a measurement accuracy that is approximately equal to that which identifies the case of low input currents at the integration stage 110 (i.e., the first current variation interval).

Finally, it is clear that modifications and variations may be made to the invention described and illustrated herein without thereby departing from the scope of the present invention, as defined in the attached claims. For example, the different embodiments described may be combined with each other so as to provide further solutions.

Furthermore, the previously described embodiments of the timer 45, the input-to-time converters 46 and the integration stage 110 of the digital detectors 16 have been provided for purely exemplary and non-limiting purposes, and other embodiments may similarly be considered in a per se obvious manner. For example, voltage-controlled timers, timers based on ring oscillators having an odd number of inverters, integration stages 110 of the digital detectors 16 each comprising only an integration circuit and a counter circuit (therefore without even comprising the respective switching circuit) or each comprising a first and a second integration circuit mutually coupled by a switching circuit, etc. may similarly be used.

Furthermore, the timer signal TM may be an analog signal and the input-to-time converters 46 may be configured to convert the respective input datum xⱼ into an analog signal and compare said analog input signal with the analog timer signal. For example, the timer signal may be a voltage ramp generated from a current, in particular from the reference current I_{REF}; in this case the update frequency of the analog timer signal is indicative of the slope of the voltage ramp.

The memory cells 20 may be resistive memory cells not based on PCM materials, but on different technologies; for example, they may be magnetoresistive (MRAM), resistive (RRAM) or static (SRAM) memory cells.

Furthermore, the storage element 25 of each memory cell 20 may be formed by a plurality of selectable resistive elements, equal to or different from each other, mutually arranged in parallel, for example between the respective bit line and ground, which may be selectively enabled or disabled when programming the memory array 12, so that the respective transconductance value gᵢⱼ may be a multibit value.

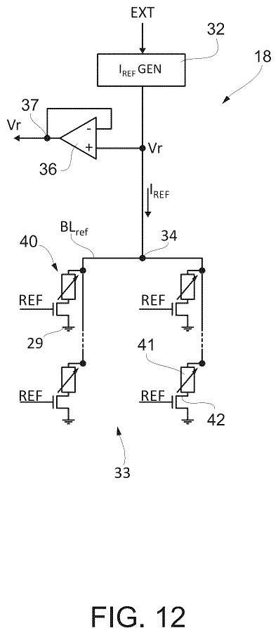

Furthermore, and as exemplarily shown in FIG. 12, the biasing circuit 18 may comprise a current source 32 generating the reference current I_{REF} and a reference network 33 having an input node 34 and a reference impedance Z_{REF}.

In this embodiment, the current source 32 is a controllable current source that receives an external signal EXT, for example from a user of the IMC device 10, which is indicative of a desired value of the reference current I_{REF}.

By varying the reference current I_{REF} through the external signal EXT it is possible to vary the oscillator current I_{OSC} and therefore modify the update frequency fᵤ of the timer signal TM<L:1> and, therefore, the total computation time of the IMC device 10. In fact, for example, an increase in the oscillator current I_{OSC} implies that the oscillator integration voltages V′_{A}, V′_{B} increase faster; consequently, the first and the second oscillator control signals OS_{A}, OS_{B} switch faster, thereby also increasing the update frequency fᵤ of the timer signal TM<L:1>.

The reference network 33 receives the reference current I_{REF} at the input node 34. The input node 34 is at a voltage that is a function of the reference current I_{REF} and the reference impedance Z_{REF}.

The biasing circuit 18 further comprises a voltage distribution circuit, here formed by an operational amplifier 36 having an output 37 providing the biasing voltage Vr.

The operational amplifier 36 has a non-inverting input coupled to the input node 34 of the reference network 33. The operational amplifier 36 has an inverting input coupled, in particular here directly coupled, to the output 37 of the operational amplifier 36.

The output 37 of the amplifier 36 is coupled to the bit lines BL₁, . . . , BL_{M}, for example directly or through a specific voltage distribution circuit, according to the specific application.

In practice, in this embodiment, the voltage at the input node 34 of the reference network 33 is the biasing voltage Vr.

In detail, in this embodiment, the reference network 33 is formed by a reference memory array, therefore also indicated hereinafter by 33, having an overall value of reference transconductance gᵣₑf and comprising one or more reference cells, here a plurality of reference cells 40, of non-volatile type.

The reference memory array 33 may be a portion of the memory array 12 or may be a separate memory array.

The reference cells 40 have the same circuit configuration as the memory cells 20 of the memory array 12.

In detail, the reference cells 40 each comprise a storage element 41 and a selection element 42, in particular equal to the storage element 25 and, respectively, to the selection element 26 of the memory cells 20.

In practice, the storage element 41 is based on the same technology used to obtain the storage element 25. For example, if the storage element 25 is based on a PCM material, then the storage element 41 is also based on a PCM material, in particular the same PCM material.

The reference cells 40 are programmed to store respective reference transconductance values, which may be equal to or different from each other, according to the specific application.

The number of reference cells 40 and the respective reference transconductance values may be chosen, in the design step, so that the reference memory array 33 is a statistically significant sample of the memory array 12.

In practice, the overall value of reference transconductance g_{ref} of the reference memory array 205 statistically represents an overall transconductance of the memory array 12.

For example, the overall transconductance of the memory array 12 may be equal to the transconductance that the memory array 12 would have if all reference cells 20 were activated simultaneously.

For example, the number of reference cells 206 may be greater than one hundred.

For example, the reference cells 40 may be programmed so that the overall reference transconductance g_{ref} of the reference memory array 33 is equal to an average value of the overall transconductance of the memory array 12.

For example, the average value may represent the average transconductance value that the memory array 12 has in use, for example as determined during a calibration or initialization step of the IMC device 10.

The storage elements 41 have a first terminal which is coupled to the input node 34 of the reference network 33 and a second terminal coupled to a reference potential node, here to ground 29, through the selection element 42.

In practice, the reference cells 40 all share a same reference bit line BLᵣₑf.

The selection elements 42 are each formed by a respective switch, for example a BJT transistor, a diode or a MOSFET transistor, here an NMOS transistor, in particular equal to the selection element 26 of the memory cells 20, which is arranged in series to the respective storage element 41.

In this embodiment, the selection elements 42 of all the reference cells 40 are controlled by a same reference activation signal REF, which for example may be generated by the word line activation circuit 14 or by other components of the IMC device 10, here not shown. However, the selection elements 42 may each be controlled by a respective reference activation signal, different from each other, for example depending on which reference cells 40 are intended to be activated, during a computation of the IMC device 10.

The reference impedance Z_{REF} is a function of the transconductance values g_{ref} stored by the reference cells 40 and of the reference activation signal REF.

The bit line currents I_{B}Li, . . . , I_{BL},M each also depend on the biasing voltage Vr received from the biasing circuit 18.

The fact that the biasing voltage Vr is generated by the reference current I_{REF} may allow the biasing voltage Vr to be adjusted by varying the variable reference impedance Z_{REF} and/or the reference current I_{REF}.

In fact, during the life of the IMC device 10 the IMC device 10 may be subject to temperature variations which may affect the transconductance values gᵢⱼ of the memory cells 20. Furthermore, the transconductance values gᵢⱼ of the memory cells 20 may be subject to drift; for example, in case the memory cells 20 are PCM memory cells, the storage elements 25 may be subject to aging phenomena such as for example amorphization.

Such deviations of the transconductance values gᵢⱼ from the programmed values may vary the bit line current I_{BL,i}, thereby causing errors in the output signal Y.

In the IMC device 10, such temperature variations or drifts would also affect, in the same manner, the reference transconductance values of the reference memory cells 40, and, consequently, the overall value of reference transconductance g_{ref} of the reference memory array 33, since the reference memory cells 40 represent a statistically significant sample of the memory cells 20.

A variation in the reference transconductance values of the reference memory cells 40 would cause a variation in the reference impedance Z_{REF} and, therefore, a variation in the voltage at the input node 34 of the reference network 33. Consequently, also the biasing voltage Vr varies.

In detail, the variation in the biasing voltage Vr compensates for the variation in the transconductance values gᵢⱼ of the memory cells 20.

For example, if the memory cells 20 undergo a drift which causes an increase in the respective transconductance values gᵢⱼ, the corresponding bit line current I_{BL,i} also increases. At the same time, the overall value of reference transconductance g_{ref} of the reference memory array 33 also increases, thus causing a decrease in the reference impedance Z_{REF} and, consequently, in the biasing voltage Vr.

A decrease in the biasing voltage Vr causes a decrease in the bit line current I_{BL,i}.

In other words, the biasing circuit 18 allows to compensate for a variation in the bit line currents I_{BL,i} caused by the drift of the transconductance values gᵢⱼ.

Furthermore, in this embodiment, since the reference current I_{REF} is generated by the current source 32 and, therefore, is not affected by drifts of the reference transconductance value gᵣₑf, the update frequency fᵤ of the timer signal TM remains constant.

Therefore, the timing of the IMC device 10 remains constant. Accordingly, the IMC device 10 has a total processing time independent of drifts that may affect the memory cells 20.

However, a user of the IMC device 10 may vary the timing of the IMC device 10, and therefore the total processing time of the IMC device 10, by varying the supply current of the timer 45, i.e., here the reference current I_{REF}, for example through the external signal EXT. Alternatively, the reference impedance Z_{REF} of the reference network 33 of FIG. 1 may be a variable impedance, for example controllable by a user in response to a drift of the memory cells 20, obtained in a manner different from what has been shown, i.e., it may not comprise the reference memory cells 40.

Furthermore, in a different embodiment the first and the second control flip-flops 107a and 107b may be absent and the first and the second control inverters 106a and 106b are replaced by respective non-inverting buffers. In this case, the switching of the set of control logic gates 109 does not necessarily occur at the rising edges of the negated clock signal CLK_N but is asynchronous. This causes the selection switches 105a and 105b and the charge counter stage 111 to operate in an asynchronous manner, but also simplifies the circuit structure of the digital detector 16.

Furthermore, although the case in which the bit line current I_{BL,i} of each bit line BLᵢ is compared by the control stage 101 has been previously described with two current references (i.e., the first and the second secondary control mirrored currents p₁·I_{bias} and p₂·I_{bias}, exemplarily equal respectively to four times and half the biasing current I_{bias}) and therefore the selection stage 102 generates the total selection current I_{sel,tot} based on three available combinatorial choices (I_{sel,tot}=k₂·I_{BL,i}+k₃·I_{BL,i}+k₄·I_{BL,i}, I_{sel,tot}=k₂·I_{BL,i}+k₃·I_{BL,i}, or I_{sel,tot}=k₂·I_{BL,i}), it is evident that this may be generalized to Z current references and Z+1 combinatorial choices for generating the total selection current I_{sel,tot}. In other words, Z+1 current variation intervals may be considered in lieu of the three previously described.

In detail, in this embodiment of the digital detector 16 (not shown and more general than that previously described), the control stage 101 comprises Z control input branches of the main current mirror 115 with the main control mirror ratio 1:k₁, which allow Z copies of the main control mirrored current kᵣ I_{BL,i} to be generated.

Each of these Z control input branches of the main current mirror 115 is connected, through a respective control input node, to a respective output branch of the secondary current mirror 144, which has Z output branches, and which therefore may generate Z different mirrored and scaled copies of the biasing current I_{bias} (i.e., the Z different current references).

The D-input of a respective control flip-flop is connected to each of the Z control input nodes.

The Q-outputs of the Z control flip-flops are connected to the set of control logic gates 109 which implements the logic functions necessary to generate the Z control signals to be sent to the selection stage 102 and to the charge counter stage 111, similarly to what has been previously described. In particular, the set of control logic gates 109 may be implemented through a common decoder which receives at input the Q-outputs of the Z control flip-flops and generates at output the respective control signals, in a per se obvious manner in view of what has been previously described and of the number and chosen arrangement of the selection switches.

The selection stage 102 comprises Z+1 selection input branches of the main current mirror 115, each with the respective selection mirror ratio, which allow Z+1 selection mirrored currents to be generated.

The selection input branches of the main current mirror 115 have the selection switches, in a number and arrangement suitable to combine with each other at the selection common node 116 the selection mirrored currents as a function of the control signals and in such a way as to have Z+1 combinatorial choices to generate the total selection current I_{sel,tot}. The total selection current I_{sel,tot} is then sampled by the integration stage 110 as previously described and the resulting charge packets are then counted by the charge counter stage 111.

In particular, the latter has Z+1 count selectors 175 coupled to the Z+1 first count flip-flops in a manner similar to what has been previously described, in such a way that the control signals allow the selection of the signal which arrives at the CK-inputs of the count flip-flops (i.e., the negated clock signal CLK_N if the respective control signal is ‘0’, or ‘1’ for the first count flip-flop 175.1 and the Q̅-output of the previous count flip-flop for the remaining Z-1 first count flip-flops if the respective control signal is ‘1’).

In particular, as the number Z increases, the measurement accuracy of the digital detector 16 increases since the size of the intervals wherein the bit line current I_{BL,i} may vary without causing a corresponding change in the selection mode of the current at the input of the integration stage 110 decreases.

For example, Z may be equal to 1 or greater than 2.

Furthermore, in general the control stage 101 is electrically coupled to at least a first bit line BLᵢ and is configured to receive the corresponding bit line current I_{BL,i}, generate at least a first main control mirrored current k₁·I_{BL,i} in response to the first bit line current I_{BL,i}, compare the first main control mirrored current k₁·I_{BL,i} with at least a first reference current (e.g., p₁·I_{bias}) and generate one or more control signals (S_{control,1}-S_{control,3}, S̅_{control,1}) indicative of said comparison. The selection stage 102 is electrically coupled to the control stage 101 and the first bit line BLᵢ and is configured to receive the bit line current I_{BL,i} and the one or more control signals and generate the total selection current I_{sel,tot} in response to the bit line current I_{BL,i} and as a function of the one or more control signals. The integration stage 110 is electrically coupled to the selection stage 102 and is configured to receive and sample the total selection current I_{sel,tot}. The charge counter stage 111 is electrically coupled to the integration stage 110 and to the control stage 101 and is configured to receive the total selection current I_{sel,tot} sampled and the one or more control signals and generate, as a function of the one or more control signals, the output signal Y in response to the sampling of the total selection current I_{sel,tot}.

1. An in-memory computation (IMC) device configured to receive an input signal indicative of a plurality of input values and to provide at least an output signal indicative of a plurality of output values, the IMC device comprising:
a word line activation circuit configured to receive the input signal and to provide a plurality of word line activation signals, each word line activation signal being a function of a respective input value of the input values;
a biasing circuit configured to provide a biasing voltage;
a memory array comprising a plurality of first memory cells coupled to a first bit line and each coupled to a respective word line, the first bit line being configured to receive the biasing voltage, the first memory cells being configured to each store a respective computational weight and to each receive from the respective word line a respective word line activation signal of the plurality of word line activation signals, the first memory cells being configured to be each traversed by a respective cell current which is a function of the biasing voltage, of the respective word line activation signal and of the respective computational weight, the first bit line being configured to be traversed by a first bit line current which is a sum of the cell currents; and
a first digital detector coupled to the first bit line and configured to sample the first bit line current and, in response to the first bit line current, provide the output signal;
wherein the first digital detector comprises:
a control stage electrically coupled to the first bit line and configured to receive the first bit line current, generate at least a first main control mirrored current in response to the first bit line current, compare the first main control mirrored current with at least a first reference current and generate one or more control signals indicative of said comparison;
a selection stage electrically coupled to the control stage and the first bit line and configured to receive the first bit line current and the one or more control signals and generate a total selection current in response to the first bit line current and as a function of the one or more control signals;
an integration stage electrically coupled to the selection stage and configured to receive and sample the total selection current; and
a charge counter stage electrically coupled to the integration stage and to the control stage and configured to receive the total selection current sampled and the one or more control signals and generate, as a function of the one or more control signals, the output signal in response to the sampled first total selection current.

2. The IMC device according to claim 1, wherein the total selection current is lower than, or equal to, the first bit line current.

3. The IMC device according to claim 1, wherein the total selection current is configured to decrease with respect to the first bit line current correspondingly to how much the first bit line current increases.

4. The IMC device according to claim 1, wherein the control stage is further configured to generate at least a second main control mirrored current in response to the first bit line current, compare the second main control mirrored current with a second reference current and generate said control signals indicative of the comparison of the first main control mirrored current with the first reference current and of the second main control mirrored current with the second reference current.

5. The IMC device according to claim 4, wherein the control stage and the selection stage comprise a main current mirror electrically coupled to the first bit line and configured to receive the first bit line current and to mirror it in at least a first and a second control input branch of the control stage and in at least a first, a second and a third selection input branch of the selection stage.

6. The IMC device according to claim 5:
wherein the main current mirror has a same main control mirror ratio for both the first control input branch and the second control input branch of the control stage;
wherein the first and the second main control mirrored currents are generated in response to the first bit line current and on the basis of the main control mirror ratio, the first main control mirrored current is configured to flow in the first control input branch up to a first control input node of the control stage and the second main control mirrored current is configured to flow in the second control input branch up to a second control input node of the control stage;
wherein the control stage further comprises a secondary current mirror configured to receive a biasing current and to mirror it into a first output branch and a second output branch of the control stage;
wherein the secondary current mirror has a first secondary control mirror ratio for the first output branch and a second secondary control mirror ratio for the second output branch in such a way that a first secondary control mirrored current flows through the first output branch and a second secondary control mirrored current through the second output branch, the first secondary control mirrored current being greater than the second secondary control mirrored current, the first secondary control mirrored current being said first reference current and the second secondary control mirrored current being said second reference current; and
wherein the first control input node is shared between the first output branch and the first control input branch and the second control input node is shared between the second output branch and the second control input branch.

7. The IMC device according to claim 6, wherein the control stage further comprises:
a first control inverter and a second control inverter respectively coupled to the first control input node and the second control input node;
a first control flip-flop and a second control flip-flop, each control flip-flop having a respective input coupled, respectively, to the first control input node and the second control input node through, respectively, the first control inverter and the second control inverter; and
a set of control logic gates which is coupled to outputs of the first control flip-flop and the second control flip-flop, to the charge counter stage and to the selection stage and is configured to generate the control signals on the basis of the outputs of the first control flip-flop and the second control flip-flop.

8. The IMC device according to claim 7:
wherein the control signals comprise a first control signal, a second control signal, a third control signal and a first negated control signal;
wherein the first control signal assumes a first logic value when the output of the first control flip-flop and the output of the second control flip-flop assume first logic values, and assumes a second logic value when the output of the first control flip-flop and the output of the second control flip-flop assume second logic values or when the output of the first control flip-flop assumes the second logic value and the output of the second control flip-flop assumes the first logic value,
wherein the second control signal assumes the first logic value when the output of the first control flip-flop assumes the second logic value and the output of the second control flip-flop assumes the first logic value, and assumes the second logic value when the output of the first control flip-flop and the output of the second control flip-flop assume the first or the second logic values;
wherein the third control signal assumes the first logic value when the output of the first control flip-flop and the output of the second control flip-flop assume the second logic values, and assumes the second logic value when the output of the first control flip-flop and the output of the second control flip-flop assume the first logic values or when the output of the first control flip-flop assumes the second logic value and the output of the second control flip-flop assumes the first logic value; and
wherein the first negated control signal assumes the first logic value when the first control signal assumes the second logic value and assumes the second logic value when the first control signal assumes the first logic value.

9. The IMC device according to claim 5:
wherein the main current mirror has a respective selection mirror ratio for each of the first selection input branch, the second selection input branch and the third selection input branch of the selection stage in such a way that in the first selection input branch, in the second selection input branch and in the third selection input branch a first selection mirrored current, a second selection mirrored current and a third selection mirrored current respectively flow;
wherein the first selection input branch, the second selection input branch and the third selection input branch share a selection common node through which the total selection current is configured to flow; and
wherein the selection stage comprises one or more selection switches which extend along at least some of the first selection input branch, the second selection input branch and the third selection input branch and are configured to receive the control signals and selectively switch as a function of the control signals in such a way as to generate at the selection common node corresponding mutual combinations, different from and alternative to each other, of the selection mirrored current, of the second selection mirrored current, and of the third selection mirrored current, the total selection current in the selection common node being defined at each time by the respective combination of the selection mirrored current, of the second selection mirrored current and of the third selection mirrored current.

10. The IMC device according to claim 1, wherein the charge counter stage comprises:
one or more count selectors which are coupled to the integration stage to receive a negated clock signal indicative of the sampling of the total selection current, are coupled to the control stage to receive the control signals and are controllable as a function of the control signals; and
a plurality of count flip-flops coupled to the one or more count selectors and configured to receive respective flip-flop input signals generated by the count selectors as a function of the control signals and generate the output signal on the basis of said flip-flop input signals.

11. The IMC device according to claim 10:
wherein the control stage is further configured to generate at least a second main control mirrored current in response to the first bit line current, compare the second main control mirrored current with a second reference current and generate said control signals indicative of the comparison of the first main control mirrored current with the first reference current and of the second main control mirrored current with the second reference current;
wherein the count selectors comprise a first count selector, a second count selector and a third count selector;
wherein each count selector has a respective first input coupled to the integration stage to receive the negated clock signal, a respective second input, a respective control input coupled to the control stage to receive a respective control signal of the control signals, and a respective output, the one or more count selectors each being configured to selectively couple the output with one of the first input and the second input as a function of the control signal at the control input;
wherein the second input of the first count selector is configured to receive a predefined logic signal;
wherein the plurality of count flip-flops comprises a first count flip-flop, a second count flip-flop, a third count flip-flop, and an F-th count flip-flop, cascading with each other;
wherein each count flip-flop has a clock input, a data input, a first output and a second output;
wherein the second input of the second count selector and the third count selector is coupled to the second output of the first count selector and the second count selector, respectively;
wherein the clock input of the first count flip-flop, the second count flip-flop and the third count flip-flop is respectively connected to the output of the first count selector, the second count selector and the third count selector and the clock input of the F-th count flip-flop is connected to the second output of the immediately preceding count flip-flop, the clock inputs of the count flip-flops being configured to receive said flip-flop input signals;
wherein the data input of the first count flip-flop, the second count flip-flop, the third count flip-flop and the F-th count flip-flop is respectively connected to the second output of the first count flip-flop, the second count flip-flop, the third count flip-flop and the F-th count flip-flop; and
wherein the first outputs of the count flip-flops are configured to generate the output signal.

12. The IMC device according to claim 1:
wherein the control stage is further configured to generate at least a second main control mirrored current in response to the first bit line current, compare the second main control mirrored current with a second reference current and generate said control signals indicative of the comparison of the first main control mirrored current with the first reference current and of the second main control mirrored current with the second reference current; and
wherein the control stage is further configured to generate at least a third main control mirrored current in response to the first bit line current, compare the third main control mirrored current with at least a third reference current, and generate the control signals also indicative of the comparison with the third reference current.

13. The IMC device according to claim 1, wherein the digital detector is configured to perform a number of successive sampling iterations and, in each sampling iteration:
the integration stage is configured to generate an integration signal indicative of a time integral of the first total selection current, compare the integration signal with a sampling threshold and reset the integration signal in response to the integration signal reaching the sampling threshold;
the integration stage comprises a first inverter having an output providing the integration signal, and an integration capacitive element coupled to the output of the first inverter, the first inverter being configured to receive the total selection current indicative of the bit line current; and
the charge counter stage is configured to update the output signal in response to the integration signal reaching the sampling threshold.

14. The IMC device according to claim 1:
wherein the biasing circuit is configured to provide the biasing voltage in response to a reference current;
wherein the biasing circuit comprises a reference network having a variable reference impedance and configured to be traversed by the reference current, the biasing voltage being a function of the reference current and the variable reference impedance; and
wherein the reference network comprises a reference memory array configured to have a reference transconductance value, the variable reference impedance being a function of the reference transconductance value, the reference memory array representing a statistically significant sample of the memory array.

15. The IMC device according to claim 1:
wherein the word line activation circuit comprises a timer configured to provide a timer signal, and a plurality of input-to-time converters electrically coupled to the timer and configured to receive the timer signal, each compare the timer signal with the respective input value of the input values and, in response, each provide the respective word line activation signal;
wherein the timer comprises a respective integration stage; and
wherein the integration stage of the digital detector has the same circuit diagram as the integration stage of the timer.

16. The IMC device according to claim 1:
wherein the memory array further comprises a plurality of second memory cells coupled to a second bit line and each coupled to a respective word line of the word lines, the second bit line being configured to receive the biasing voltage, the second memory cells being configured to each store a respective computational weight and to each receive a respective word line activation signal of the plurality of word line activation signals from the respective word line, the second memory cells being configured to be each traversed by a respective cell current which is a function of the biasing voltage, of the respective word line activation signal and of the respective computational weight, the second bit line being configured to be traversed by a second bit line current which is a sum of the cell currents of the second memory cells;
wherein the IMC device further comprises a second digital detector coupled to the second bit line and configured to sample the second bit line current and, in response to the second bit line current, provide the output signal; and
wherein the second digital detector comprises:
a respective control stage electrically coupled to the second bit line and configured to receive the second bit line current, generate at least a respective first main control mirrored current in response to the second bit line current, compare the respective first main control mirrored current with at least one respective first reference current and generate one or more respective control signals indicative of said comparison;
a respective selection stage electrically coupled to the control stage of the second digital detector and to the second bit line and configured to receive the second bit line current and the one or more respective control signals and generate a respective total selection current in response to the second bit line current and as a function of one or more respective control signals;
a respective integration stage electrically coupled to the selection stage of the second digital detector and configured to receive and sample the respective total selection current; and
a respective charge counter stage electrically coupled to the integration stage and to the control stage of the second digital detector and configured to receive the respective total selection current sampled and the one or more respective control signals and generate, as a function of the one or more respective control signals, the output signal in response to the sampling of the second total selection current.

17. A method for controlling the (IMC) device of claim 1, comprising:
providing, by the word line activation circuit, the plurality of word line activation signals to the first memory cells;
generating, by the biasing circuit, the biasing voltage and applying the biasing voltage to the first bit line;
generating, by the control stage, the at least a first main control mirrored current in response to the first bit line current;
comparing, by the control stage, the at least a first main control mirrored current with the at least a first reference current;
generating, by the control stage, the one or more control signals indicative of said comparison;
generating, by the selection stage, the total selection current in response to the first bit line current and as a function of the one or more control signals;
sampling, by the integration stage, the total selection current; and
generating, by the charge counter stage and as a function of the one or more control signals, the output signal in response to sampling the first total selection current.
